(19) United States
(12) Patent Application Publication
(10) Pub. No.: US 2025/0331160 A1
(43) Pub. Date: Oct. 23, 2025

(54) SEMICONDUCTOR DEVICE AND FABRICATION METHOD THEREOF

(71) Applicant: Yangtze Memory Technologies Co., Ltd., Wuhan, Hubei (CN)

(72) Inventors: Zongliang HUO, Wuhan (CN); Wei XU, Wuhan (CN); Wenbin ZHOU, Wuhan (CN); Jingyu ZHAI, Wuhan (CN); Bin YUAN, Wuhan (CN)

(21) Appl. No.: 18/890,380

(22) Filed: Sep. 19, 2024

(30) Foreign Application Priority Data
Apr. 17, 2024 (CN) 202410468622.0

(51) Int. Cl. H10B 12/00

(52) U.S. Cl. CPC H10B 12/315; H10B 12/02; H10B 12/482; H10B 12/488

(57) ABSTRACT

Semiconductor devices, fabrication methods of such semiconductor devices, systems including such semiconductor devices are provided. In one aspect, a fabrication method of a semiconductor device includes: forming a conductive structure having a first surface and a second surface opposite to each other along a first direction, the conductive structure including at least a metal semiconductor compound layer extending along the first direction; forming a semiconductor body located on the first surface of the conductive structure and connected with the metal semiconductor compound layer; and forming a storage structure located on the second surface of the conductive structure and connected with the metal semiconductor compound layer.

### CROSS-REFERENCE TO RELATED APPLICATIONS

This application claims the benefit of priority to Chinese Patent Application No. 202410468622.0, filed on Apr. 17, 2024, the disclosure of which is hereby incorporated by reference in its entirety.

### TECHNICAL FIELD

The present disclosure relates to the field of semiconductor technology, and in particular, to a semiconductor device and a fabrication method thereof.

### BACKGROUND

A semiconductor device, e.g., a dynamic random access memory (DRAM), is one of the most important access components in an electronic system. Typically, one transistor and one capacitor are employed to constitute a 1T1C structure as one memory cell. This 1T1C structure enables the dynamic random access memory to have a higher integration level and a lower cost, and plays an irreplaceable role in a computer access device. With the rapid development of the semiconductor technology, the dynamic random access memory is rapidly developing towards a higher density and a higher quality.

### SUMMARY

According to one aspect of the present disclosure, there is provided a semiconductor device, comprising: a conductive structure having a first surface and a second surface disposed oppositely along a first direction, wherein the conductive structure comprises at least a metal semiconductor compound layer extending along the first direction; a semiconductor body located on the first surface of the conductive structure and connected with the metal semiconductor compound layer; and a storage structure located on the second surface of the conductive structure and connected with the metal semiconductor compound layer.

In some implementations, the conductive structure is entirely the metal semiconductor compound layer.

In some implementations, the conductive structure further comprises a semiconductor layer that is in contact with the semiconductor body and surrounded by the metal semiconductor compound layer.

In some implementations, a metal element in the metal semiconductor compound layer comprises nickel, cobalt or titanium; and the semiconductor layer comprises a monocrystalline material.

In some implementations, the conductive structure comprises at least a first portion; and a side of the first portion is aligned with a side of the semiconductor body along the first direction.

In some implementations, the conductive structure further comprises a second portion surrounding the first portion; a sum of sizes of cross sections of the first portion and the second portion perpendicular to the first direction is greater than a size of a cross section of the semiconductor device body perpendicular to the first direction.

In some implementations, the conductive structure and the semiconductor body form a step structure at a joint of the conductive structure and the semiconductor body; and the step structure comprises a side extending along the first direction and a stepped face extending along a second direction perpendicular to the first direction.

In some implementations, a size of the step structure along the second direction is the same in the first direction; and a size of the step structure along the first direction is the same in the second direction.

In some implementations, no interface is present between the semiconductor layer in the conductive structure and the semiconductor body.

In some implementations, the semiconductor body extends along the first direction; the conductive structure has doping ions therein; and a type of the doping ions is the same as a doping type of doping ions in two opposite ends of the semiconductor body along the first direction.

In some implementations, a plurality of the semiconductor bodies and a plurality of the conductive structures are comprised. The semiconductor device further comprises: a first dielectric layer between a plurality of the conductive structures; and a second dielectric layer between a plurality of the semiconductor bodies, wherein the first dielectric layer and the second dielectric layer comprise the same material or different materials; the first dielectric layer and the second dielectric layer both comprise an oxide; or, the first dielectric layer comprises a nitride, and the second dielectric layer comprises an oxide.

In some implementations, a plurality of the semiconductor bodies, a plurality of the conductive structures and a plurality of the storage structures are comprised, and a plurality of the semiconductor bodies are arranged in an array. The semiconductor device further comprises: a plurality of word lines, wherein each word line is coupled with at least one side of each semiconductor body in one row of the semiconductor bodies; and a plurality of bit lines, wherein each bit line is coupled with one of two oppositely disposed surfaces of each semiconductor body in one column of the semiconductor bodies along the first direction that is away from the conductive structure.

In some implementations, the word line is located on one side of the semiconductor body; or, the word line is located on two oppositely disposed sides of the semiconductor body; or, the word line surrounds a side of the semiconductor body.

In some implementations, two adjacent semiconductor bodies form one semiconductor body group, and the two semiconductor bodies in one semiconductor body group are separated by a first isolation structure; two adjacent semiconductor body groups are separated by a second isolation structure; and each of two of the word lines is located on a side of both sides of a respective semiconductor body in the semiconductor body group away from the first isolation structure.

In some implementations, a size of a cross section of an end of the storage structure proximal to the conductive structure perpendicular to the first direction is greater than a size of a cross section of an end of the storage structure away from the conductive structure perpendicular to the first direction.

In some implementations, the storage structure comprises a capacitor; and the capacitor comprises a cup-shaped capacitor, a cylinder-shaped capacitor or a pillar-shaped capacitor.

According to another aspect of the present disclosure, there is provided a fabrication method of a semiconductor device, comprising: forming a conductive structure having a first surface and a second surface disposed oppositely along a first direction, wherein the conductive structure comprises at least a metal semiconductor compound layer extending along the first direction; forming a semiconductor body located on the first surface of the conductive structure and connected with the metal semiconductor compound layer; and forming a storage structure located on the second surface of the conductive structure and connected with the metal semiconductor compound layer.

In some implementations, forming the semiconductor body and the conductive structure comprises: forming a plurality of initial semiconductor bodies extending along the first direction, wherein the plurality of initial semiconductor bodies are separated by an initial dielectric layer; removing part of the initial dielectric layer along the first direction to expose part of the initial semiconductor body, wherein the remaining initial semiconductor body forms the semiconductor body; metallizing at least part of the exposed initial semiconductor body to form the metal semiconductor compound layer; and configuring the metallized exposed initial semiconductor body as the conductive structure.

In some implementations, the fabrication method further comprises: forming a semiconductor thickening layer at a periphery of the exposed initial semiconductor body by an epitaxy process before metallizing at least part of the exposed initial semiconductor body; at least metallizing at least part of the semiconductor thickening layer and the exposed initial semiconductor body to form the metal semiconductor compound layer; and configuring the metallized exposed initial semiconductor body and semiconductor thickening layer as the conductive structure.

In some implementations, the fabrication method further comprises: after forming a plurality of the conductive structures, filling a first dielectric layer between the plurality of the conductive structures, wherein the remaining initial dielectric layer forms a second dielectric layer; and a material of the first dielectric layer is different from a material of the second dielectric layer.

In some implementations, forming the semiconductor body and the conductive structure comprises: forming an initial semiconductor body extending along the first direction, wherein a plurality of initial semiconductor bodies are separated by an initial dielectric layer; and one of two surfaces of the initial semiconductor body disposed oppositely along the first direction is exposed; metallizing part of the initial semiconductor body with the exposed surface to form the metal semiconductor compound layer; and configuring the metal semiconductor compound layer as the conductive structure, wherein the remaining portion of the initial semiconductor body that is not metallized forms the semiconductor body.

In some implementations, a plurality of the initial semiconductor bodies are comprised, and a plurality of the conductive structures and a plurality of the semiconductor bodies are formed and comprised; and a material of a first dielectric layer between the plurality of the conductive structures is the same as a material of a second dielectric layer between the plurality of the semiconductor bodies.

In some implementations, forming the semiconductor body and the conductive structure comprises: forming a plurality of initial semiconductor bodies extending along the first direction, wherein the plurality of initial semiconductor bodies are separated by an initial dielectric layer; removing part of the initial semiconductor body to form a second trench in the initial dielectric layer, wherein the remaining initial semiconductor body forms the semiconductor body; widening the second trench to form a first trench, wherein a size of the first trench along a second direction perpendicular to the first direction is greater than a size of the second trench along the second direction; and forming the conductive structure in the first trench.

In some implementations, forming the conductive structure in the first trench comprises: forming an initial semiconductor layer in the first trench; and metallizing the initial semiconductor layer to form the metal semiconductor compound layer.

In some implementations, the forming the initial semiconductor layer in the first trench comprises: forming the initial semiconductor layer in the first trench by a deposition process, wherein the initial semiconductor layer comprises a polycrystalline material.

In some implementations, the forming the initial semiconductor layer in the first trench comprises: forming the initial semiconductor layer in the first trench by an epitaxy process, wherein the initial semiconductor layer comprises a monocrystalline material.

In some implementations, forming the metal semiconductor compound layer comprises: forming an initial metal layer covering an exposed surface of a structure to be metallized; and annealing the structure to be metallized formed with the initial metal layer to form the metal semiconductor compound layer.

In some implementations, the fabrication method further comprises: forming a word line on at least one side of the semiconductor body; and forming a bit line on one of two oppositely disposed surfaces of the semiconductor body along the first direction away from the conductive structure.

In some implementations, the forming the word line on at least one side of the semiconductor body comprises: forming the word line on one side of the semiconductor body; forming the word line on each of two oppositely disposed sides of the semiconductor body; or forming the word line surrounding a side of the semiconductor body.

In some implementations, two adjacent semiconductor bodies form one semiconductor body group, and the two semiconductor bodies in one semiconductor body group are separated by a first isolation structure; two adjacent semiconductor body groups are separated by a second isolation structure; and forming the word line on at least one side of the semiconductor body comprises: forming the word line on a side of both sides of a respective semiconductor body in the semiconductor body group away from the first isolation structure.

In some implementations, the storage structure comprises a capacitor; and forming the storage structure comprises: forming a cup-shaped capacitor, a cylinder-shaped capacitor or a pillar-shaped capacitor.

The implementations of the present disclosure provide a semiconductor device and a fabrication method thereof, wherein the fabrication method of the semiconductor device comprises: forming a conductive structure having a first surface and a second surface disposed oppositely along a first direction, wherein the conductive structure comprises at least a metal semiconductor compound layer extending along the first direction; forming a semiconductor body located on the first surface and connected with the metal semiconductor compound layer; and forming a storage structure located on the second surface and connected with the metal semiconductor compound layer. In the implementations of the present disclosure, by forming at least the metal semiconductor compound layer extending along the first direction, self-alignment of the conductive structure and the semiconductor body can be realized. On the one hand, the alignment accuracy of the conductive structure with the semiconductor body can be improved; the alignment difficulty of both is reduced; the reliability of the semiconductor device is improved; the fabrication time and cost are saved; and the process speed and efficiency are increased. On the other hand, the metal semiconductor compound layer serves as a material of the conductive structure between the semiconductor body and the storage structure and has a lower electrical resistivity, and can realize a better electrical connection between the semiconductor body and the storage structure and improve the reliability of the semiconductor device.

### BRIEF DESCRIPTION OF THE DRAWINGS

FIG. 1 is a schematic structural diagram I of a dynamic random access memory provided by implementations of the present disclosure;

FIGS. 2a to 2d are schematic structural diagrams of a conductive structure during a fabrication process provided by implementations of the present disclosure;

FIG. 3 is a schematic flow diagram of a fabrication method of a semiconductor device provided by implementations of the present disclosure;

FIGS. 4a to 4d are cross-sectional schematic diagrams during a process of forming an initial semiconductor body provided by implementations of the present disclosure;

FIGS. 5a to 5d are cross-sectional schematic diagrams I during a process of forming a conductive structure and a semiconductor body provided by implementations of the present disclosure;

FIGS. 6a to 6c are cross-sectional schematic diagrams I of different proportions of a semiconductor material in a metal semiconductor compound layer during several metallization processes provided by implementations of the present disclosure;

FIGS. 7a to 7e are cross-sectional schematic diagrams II during a process of forming a conductive structure and a semiconductor body provided by implementations of the present disclosure;

FIGS. 8a to 8d are cross-sectional schematic diagrams III during a process of forming a conductive structure and a semiconductor body provided by implementations of the present disclosure;

FIGS. 9a to 9e are cross-sectional schematic diagrams IV during a process of forming a conductive structure and a semiconductor body provided by implementations of the present disclosure;

FIGS. 10a to 10i are cross-sectional schematic diagrams V during a process of forming a conductive structure and a semiconductor body provided by implementations of the present disclosure;

FIGS. 11a to 11c are cross-sectional schematic diagrams VI during a process of forming a conductive structure and a semiconductor body provided by implementations of the present disclosure;

FIGS. 12a to 12d are cross-sectional schematic diagrams II of different proportions of a semiconductor material in a metal semiconductor compound layer during several metallization processes provided by implementations of the present disclosure;

FIG. 13 is a schematic structural diagram II of a dynamic random access memory provided by implementations of the present disclosure; and

FIG. 14 is a schematic structural diagram III of a dynamic random access memory provided by implementations of the present disclosure;

In the drawings (which are not necessarily drawn to scale), similar reference signs may describe similar parts in different views. Similar reference signs with different letter suffixes may represent different instances of similar parts. The drawings generally illustrate the various implementations discussed herein by way of implementations rather than limitation.

### DETAILED DESCRIPTION

Implementation implementations disclosed by the present disclosure will be described below in more details with reference to the drawings. Although the implementation implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey a scope disclosed by the present disclosure to those skilled in the art.

In the following description, numerous specific details are given in order to provide a more thorough understanding of the present disclosure. However, it is apparent to those skilled in the art that the present disclosure may be practiced without one or more of these details. In other instances, in order to avoid confusion with the present disclosure, some technical features well-known in the field are not described. That is, all the features of the actual implementations are not described here, and well-known functions and structures are not described in detail.

In the drawings, the sizes of a layer, a region, and an element and their relative sizes may be exaggerated for clarity. Like reference numerals denote like elements throughout the disclosure.

It should be understood that, spatially relative terms, such as “beneath”, “below”, “lower”, “under”, “over”, “upper”, and the like, may be used herein for ease of description to describe the relationship between one element or feature and other elements or features as illustrated in the figures. It is to be understood that, the spatially relative terms are intended to further encompass different orientations of a device in use or operation in addition to the orientation depicted in the figures. For example, if the device in the drawings is flipped over, then the elements or the features described as “below” or “under” or “beneath” other elements may be oriented “on” the other elements or features. Therefore, the example terms “below” and “beneath” may comprise both upper and lower orientations. The device may be orientated otherwise (rotated by 90 degrees or at other orientations), and the spatially descriptive terms used herein are interpreted accordingly.

The terms used herein are only intended to describe the specific implementations, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

In order to be capable of understanding the characteristics and the technical contents of the implementations of the present disclosure in more detail, implementation of the implementations of the present disclosure is set forth in detail below in conjunction with the drawings, and the appended drawings are only used for reference and illustration, instead of being used to limit the implementations of the present disclosure.

The semiconductor device to which the implementations of the present disclosure relate is at least a part to be used in subsequent processes to form a final device structure. Here, the final device may comprise a memory that includes, but is not limited to, a dynamic random access memory. The description is made below only taking a dynamic random access memory as an example. It is to be noted that the description of the following implementations with respect to the dynamic random access memory is only used to illustrate the present disclosure rather than to limit the scope of the present disclosure.

With the development of a dynamic random access memory technology, the size of the memory cell is increasingly smaller, and its array architecture changes from 8F2 to 6F2 and to 4F2. In addition, based on the requirements in the dynamic random access memory for an ion and leak current, an architecture of the memory changes from a planar array transistor to a recess gate array transistor, then from the recess gate array transistor to a buried channel array transistor, and then from the buried channel array transistor to a vertical channel array transistor.

In some implementations of the present disclosure, regardless of the planar transistor or the buried transistor, the dynamic random access memory comprises a plurality of memory cells each comprising one transistor and one capacitor manipulated by the transistor, that is, the dynamic random access memory comprises an architecture of 1 transistor (T) and 1 capacitor (C) (1T1C). Its main operating principle is to represent whether a binary bit is 1 or 0 using an amount of charges stored in the capacitor.

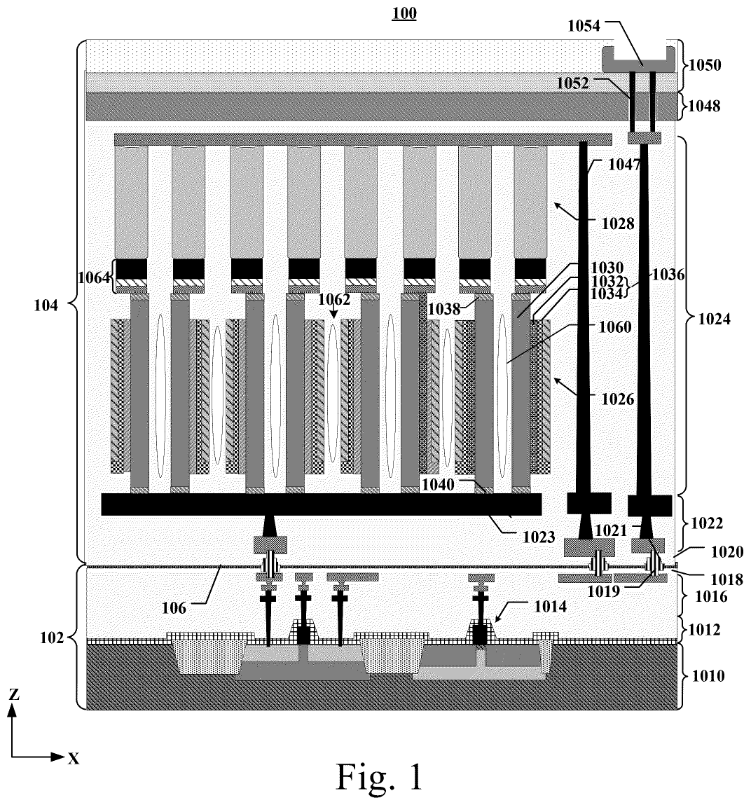

One of architectures of the dynamic random access memory is described in detail below with reference to FIG. 1. Before introducing a semiconductor device illustrated in FIG. 1, directions that may be used in the following description are defined first. An extending direction of a semiconductor body is defined as a first direction (i.e., a Z direction). A second direction (i.e., an X direction) and a third direction (i.e., a Y direction) that intersect are defined in a plane perpendicular to the Z direction. In some implementations, every two of the X direction, the Y direction and the Z direction may be perpendicular to each other.

There is shown a cross-sectional view of a three-dimensional (3D) dynamic random access memory 100 comprising a vertical transistor provided in implementations of the present disclosure. As shown in FIG. 1, the dynamic random access memory 100 comprises a first device 102 and a second device 104 stacked over the first device 102 along a Z axis direction. The first device 102 and the second device 104 are connected by a bonding interface 106. The first device 102 and the second device 104 may be connected by hybrid bonding or the like. In some implementations, the second device 104 may be bonded to a top of the first device 102 in a face-to-face manner at the bonding interface 106. The first device 102 may comprise a first substrate 1010, a peripheral circuit 1012 on a side of the first substrate 1010, and a first interconnection layer 1016 on a side of the peripheral circuit 1012 away from the first substrate 1010, wherein the first interconnection layer 1016 is configured to transfer an electrical signal of the peripheral circuit 1012. The peripheral circuit 1012 may comprise a plurality of transistors 1014. In some implementations, a trench isolation (e.g., shallow trench isolation, STI) and a doped region (e.g., a well, a source and a drain of the transistor 1014) may be also formed on or in the first substrate 1010.

The first device 102 may further comprise a first bonding layer 1018 at the bonding interface 106 and on a side of the first interconnection layer 1016 away from the peripheral circuit 1012. The first bonding layer 1018 may comprise a plurality of first bonding contacts 1019 and a dielectric that electrically isolates the first bonding contacts 1019. The first bonding contacts 1019 and the surrounding dielectric in the first bonding layer 1018 may be used for hybrid bonding. Correspondingly, the second device 104 may also comprise a second bonding layer 1020 at the bonding interface 106 and on a side of the first bonding layer 1018 away from the first interconnection layer 1016. The second bonding layer 1020 may comprise a plurality of second bonding contacts 1021 and a dielectric that electrically isolates the second bonding contacts 1021. The second bonding contacts 1021 and the surrounding dielectric in the second bonding layer 1020 may be used for hybrid bonding. Here, the second bonding contacts 1021 are in contact with the first bonding contacts 1019 at the bonding interface 106.

In some implementations, the peripheral circuit 1012 may further comprise a word line driver/row decoder coupled to a word line (WL) in a second interconnection layer 1022 through the second bonding contacts 1021 in the second bonding layer 1020 and the first bonding contacts 1019 in the first bonding layer 1018 as well as the first interconnection layer 1016. In some other implementations, the peripheral circuit 1012 may further comprise a bit line driver/column decoder coupled to a bit line 1023 (BL) in the second interconnection layer 1022 through the second bonding contacts 1021 in the second bonding layer 1020 and the first bonding contacts 1019 in the first bonding layer 1018 as well as the first interconnection layer 1016. Here, the second interconnection layer 1022 comprises the bit line 1023 over the second bonding layer 1020, and the bit line 1023 is configured to transfer an electrical signal. Instead of bonding for connecting the first device 102 and the second device 104 disposed as being stacked, in some other implementations, the first device 102 and the second device 104 disposed as being stacked may be integrated on the same substrate (there is only the first substrate and no second substrate), and may be connected directly through one or more interconnection layers between the first device 102 and the second device 104. At this time, the first bonding layer 1018 and the first bonding contacts 1019 do not exist in the first device 102; the second bonding layer 1020 and the second bonding contacts 1019 do not exist in the second device 104; and the bonding interface 106 between the first device 102 and the second device 104 does not exist as well.

With reference to FIG. 1, the second device 104 further comprises a memory cell array on the second interconnection layer 1022. The memory cell array may comprise a plurality of memory cells 1024, a second substrate 1048 on the memory cells 1024, and a third interconnection layer 1050 on the second substrate 1048. The cross section of the dynamic random access memory 100 in FIG. 1 may be taken along a bit line direction (an X axis direction), and one bit line 1023 in the second interconnection layer 1022 laterally extending in the X axis direction may be coupled to one column of memory cells 1024.

Here, each memory cell 1024 may comprise a vertical transistor 1026 and a capacitor structure 1028 coupled to the vertical transistor 1026. The vertical transistor 1026 comprises a semiconductor body 1030 extending vertically (in a Z axis direction), and a gate structure 1036 in contact with one side of the semiconductor body 1030 in the bit line direction (i.e., the X axis direction). In some other implementations, the gate structure may also completely surround the semiconductor body, half surround the semiconductor body, or is located on two opposite sides of the semiconductor body, etc., which is no longer repeated here. Here, the gate structure 1036 comprises a gate electrode 1034 and a gate dielectric 1032 between the gate electrode 1034 and the semiconductor body 1030 in the bit line direction (the X axis direction). In some implementations, the gate dielectric 1032 adjoins one side of the semiconductor body 1030, and the gate electrode 1034 adjoins the gate dielectric 1032.

In some implementations, the semiconductor body 1030 has two ends (an upper end and a lower end) in the vertical direction (the Z axis direction), and one end (e.g., the lower end in FIG. 1) extends beyond the gate dielectric 1032 and into an interlayer dielectric (ILD) layer in the vertical direction (the Z axis direction), while the other end of the semiconductor body 1030 (e.g., the upper end in FIG. 1) is flush with a corresponding end of the gate dielectric 1032. In some other implementations, the two ends (the upper end and the lower end) of the semiconductor body 1030 respectively extend beyond the gate electrode 1034 and into the ILD layer in the vertical direction (the Z axis direction). In other words, the semiconductor body 1030 may have a greater vertical size than the vertical size (e.g., the depth in the Z axis direction) of the gate electrode 1034, and neither the upper end nor the lower end of the semiconductor body 1030 is flush with a corresponding end of the gate electrode 1034. As such, a short circuit between the bit line 1023 and the word line/gate electrode 1034 or between the word line/gate electrode 1034 and the capacitor structure 1028 may be avoided.

The vertical transistor 1026 may further comprise a source 1038 and a drain 1040 disposed at two ends (the upper end and the lower end) of the semiconductor body 1030 respectively in the vertical direction (the Z axis direction), wherein the positions of the source and the drain may be interchanged, and the upper end being the source 1038 and the lower end being the drain 1040 are taken as an example here and below. In some implementations, the source 1038 is coupled to the capacitor 1028, and the drain 1040 is coupled to the bit line 1023.

Since the gate electrode may be a part of the word line or extend as the word line in a word line direction, the second device 104 of the dynamic random access memory 100 may also comprise a plurality of word lines each extending in the word line direction (the Y axis direction). Here, each word line 1034 may be coupled to one row of memory cells 1024.

The vertical transistor 1026 extends vertically through the word line 1034 and is in contact with the word line 1034, and the vertical transistor 1026 is in contact with the bit line 1023 at the drain 1040 at its lower end. Therefore, due to the vertical arrangement of the vertical transistor 1026, the word line 1034 and the bit line 1023 can be disposed in different planes in the vertical direction, which simplifies routing of the word line 1034 and the bit line 1023. Here, the vertical transistor 1026 may be arranged in a mirror-symmetrical manner so as to increase the density of the memory cells 1024 in the bit line direction (the X axis direction). Two adjacent ones of the vertical transistors 1026 in the bit line direction are mirror-symmetrical to each other with respect to a trench isolation 1060. That is to say, the second device 104 may comprise a plurality of trench isolations 1060, wherein each trench isolation 1060 extends in parallel with the word line 1034 in the word line direction (the Y axis direction), and is disposed between two adjacent rows of semiconductor bodies 1030 of the vertical transistors 1026. In some implementations, the rows of vertical transistors 1026 separated by the trench isolation 1060 are mirror-symmetrical to each other with respect to the trench isolation 1060. It should be understood that the trench isolation 1060 may comprise an air gap each laterally disposed between adjacent ones of the semiconductor bodies 1030. The second device 104 may further comprise a plurality of gate isolations 1062, wherein each gate isolation 1062 extends in parallel with the word line 1034 in the word line direction (the Y axis direction), and is disposed between two adjacent rows of word lines 1034 of the vertical transistors 1026. It should be understood that the sizes of the gate isolation 1062 and the word line 1034 in the bit line direction (the X axis direction) may be the same as or different from the size of the trench isolation 1060 in the bit line direction (the X axis direction). When the sizes of both in the bit line direction (the X axis direction) are different, spacings between a plurality of semiconductor bodies 1030 arranged along the bit line direction (the X axis direction) are different. i.e., the plurality of semiconductor bodies 1030 arranged along the bit line direction (the X axis direction) are arranged nonuniformly.

As shown in FIG. 1, the capacitor structure 1028 is located above and in contact with the source 1038 of the vertical transistor 1026 (i.e., an upper end of the semiconductor body 1030). The capacitor structure 1028 may be a vertical capacitor.

In some implementations, a conductive structure 1064 is formed between the capacitor structure 1028 and the vertical transistor 1026 to reduce the contact resistance. As shown in FIG. 1, the conductive structure 1064 may comprise a semiconductor layer, a metal semiconductor compound layer and a metal layer disposed as being sequentially stacked from bottom to top.

As shown in FIG. 1, the second device 104 may further comprise a capacitor contact 1047 in contact with a common plate of the vertical transistors 1026 to couple a second electrode 1046 of the capacitor structure 1028 to the peripheral circuit 1012 or directly couple the second electrode 1046 of the capacitor structure 1028 to the ground. In some implementations, the ILD layer for forming the capacitor structure 1028 includes the same dielectric material as the two ILD layers into which the semiconductor bodies 1030 extend, e.g., silicon oxide. A configuration of the capacitor structure 1028 may include any suitable structure and configuration, e.g., a planner capacitor, a stack capacitor, a multi-fin capacitor, a cylinder capacitor, a trench capacitor or a substrate-plate capacitor.

As shown in FIG. 1, the vertical transistor 1026 extends vertically through the word line 1034 and is in contact with the word line 1034. The vertical transistor 1026 is in contact with the bit line 1023 at the drain 1040 at its lower end, and is in contact with the capacitor structure 1028 at the source 1038 at its upper end. That is, due to the vertical arrangement of the vertical transistor 1026, the bit line 1023 and the capacitor structure 1028 can be disposed in different planes in the vertical direction, and coupled to opposite ends of the vertical transistor 1026 of the memory cell 1024 in the vertical direction. In some implementations, the bit line 1023 and the capacitor structure 1028 are disposed on opposite sides of the vertical transistor 1026 in the vertical direction, which simplifies the routing of the bit line 1023 and reduces a coupling capacitance between the bit line 1023 and the capacitor structure 1028, compared with a memory cell where a bit line and a capacitor structure are disposed on the same side of a planar transistor.

In some implementations, the vertical transistor 1026 is disposed vertically between the capacitor structure 1028 and the bonding interface 106. That is, the vertical transistor 1026 may be arranged closer to the peripheral circuit 1012 and the bonding interface 106 of the first device 102 than the capacitor structure 1028. Since the bit line 1023 and the capacitor structure 1028 are coupled to the opposite ends of the vertical transistor 1026, the bit line 1023 (serving as part of the second interconnection layer 1022) is disposed vertically between the vertical transistor 1026 and the bonding interface 106 to reduce a routing distance and the complexity of interconnection.

In some implementations, the second device 104 further comprises a second substrate 1048 disposed above the memory cell 1024, and a pad-out third interconnection layer 1050 above the memory cell 1024. The pad-out third interconnection layer 1050 may comprise an interconnection in one or more ILD layers, e.g., a contact pad 1054.

In some implementations, the second device 104 further comprises one or more contacts 1052 that extend through part of the pad-out third interconnection layer 1050 and the second substrate 1048 to couple the pad-out third interconnection layer 1050 to the memory cell 1024 and the second interconnection layer 1022. As such, the peripheral circuit 1012 can be coupled to the memory cell 1024 through the first interconnection layer 1016 and the second interconnection layer 1022 as well as the second bonding layer 1020 and the first bonding layer 1018, and the peripheral circuit 1012 and the memory cell 1024 can be coupled to an external circuit through the contacts 1052 and the pad-out third interconnection layer 1050.

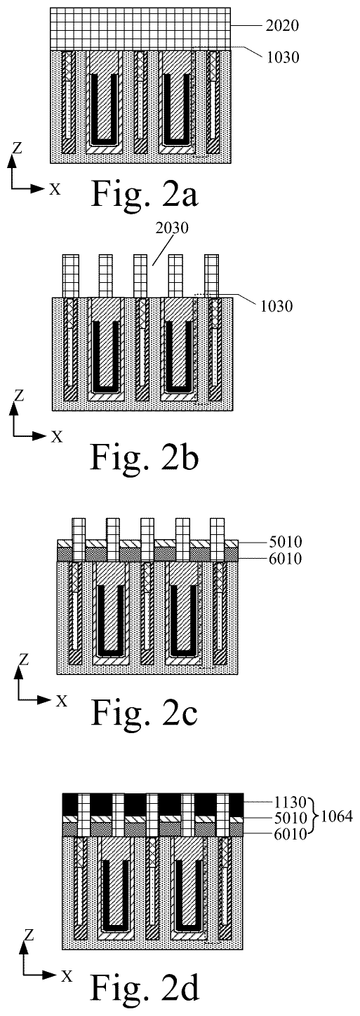

As described previously, in order to reduce the contact resistance between the capacitor structure 1028 and the vertical transistor 1026, the conductive structure 1064 is disposed between the capacitor structure 1028 and the vertical transistor 1026. The implementations of the present disclosure provide a fabrication method of a conductive structure 1064 with reference to FIGS. 2a to 2d.

As shown in FIG. 2a, a mask layer 2020 is formed on the semiconductor body 1030 (which is subsequently used to form the aforementioned vertical transistor 1026).

As shown in FIG. 2b, a conductive hole 2030 is formed in the mask layer 2020 using a self-alignment technique to expose a surface of the semiconductor body 1030 proximal to the mask layer 2020.

As shown in FIG. 2c, a semiconductor material (e.g., polysilicon) is deposited in the conductive hole 2030. In an example, the semiconductor material is doped and is etched back (EB) to form a semiconductor layer 6010; and then a metal semiconductor compound layer 5010, e.g., cobalt silicide (CoSi), is formed on the semiconductor layer.

As shown in FIG. 2d, a metal material is deposited in the conductive hole 2030 and is subjected to chemical mechanical polish (CMP) to form a metal layer 1130 (such as titanium nitride (TiN), tungsten (W), etc.) on the metal semiconductor compound layer 5010. The semiconductor layer 6010, the metal semiconductor compound layer 5010 and the metal layer 1130 form the conductive structure 1064.

In the above-mentioned implementations, the accuracy of alignment between the semiconductor body 1030 and the conductive structure greatly relies on the pattern accuracy of the mask layer, and a high requirement is imposed on a lithographic process for the mask layer; meanwhile, a depth difference between the semiconductor body and the word line in the Z axis direction, technical defects existing during a process of forming the metal silicide layer, etc., result in an increased alignment difficulty between the conductive structure 1064 and the semiconductor body 1030. Moreover, there is also the problem of an increased fabrication cost of the mask layer and the like.

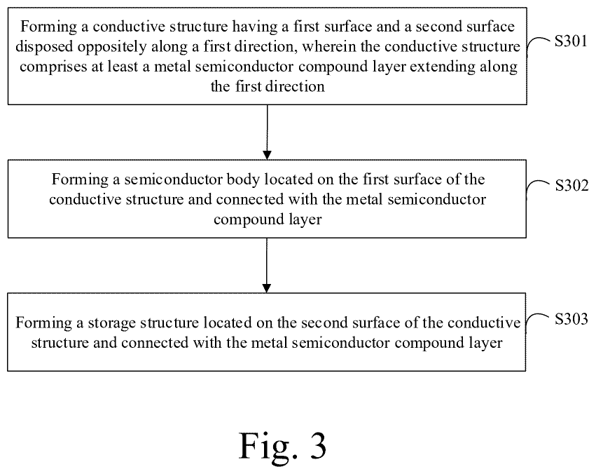

On this basis, in order to solve one or more of the above problems, the implementations of the present disclosure further provide a fabrication method of a semiconductor device. With reference to FIG. 3, FIG. 3 is a schematic flow diagram of a fabrication method of a semiconductor device provided by implementations of the present disclosure. The manufacturing method comprises: operation S301 of forming a conductive structure having a first surface and a second surface disposed oppositely along a first direction, wherein the conductive structure comprises at least a metal semiconductor compound layer extending along the first direction; operation S302 of forming a semiconductor body located on the first surface of the conductive structure and connected with the metal semiconductor compound layer; and operation S303 of forming a storage structure located on the second surface of the conductive structure and connected with the metal semiconductor compound layer.

It should be understood that the operations as illustrated in FIG. 3 are not exclusive, and other operations may be also performed before, after, or between any of the illustrated operations. A sequence of the operations illustrated in FIG. 3 can be adjusted according to actual needs. It is to be noted that the semiconductor device may comprise one conductive structure, one semiconductor body and one storage structure, or a plurality of conductive structures, a plurality of semiconductor bodies and a plurality of storage structures. The semiconductor device comprising a plurality of semiconductor structures, a plurality of semiconductor bodies and a plurality of storage structures is taken as an example here and below.

As described above, there may be a plurality of different relative positions between a gate structure and the semiconductor body in the semiconductor device, and particular fabrication approaches corresponding to different relative positions are different. In implementations of the present disclosure, a description is made by using an example in which two gate structures corresponding to two adjacent ones of the semiconductor bodies are disposed back to back (a back-to-back arrangement is shown in FIG. 1). On this basis, the semiconductor device may comprise a plurality of conductive structures, a plurality of semiconductor bodies and a plurality of storage structures arranged in an array along the X axis direction and the Y axis direction. It should be appreciated that the following description about a method of forming a semiconductor structure is only used to illustrate the present disclosure and not intended to define the scope of the present disclosure.

There may be a plurality of methods of forming the conductive structure and the semiconductor body, and several exemplary methods are illustrated in the implementations of the present disclosure. A formation process of a plurality of conductive structures and a plurality of semiconductor bodies is described in detail below in conjunction with the drawings.

During the process of performing operation S301 to step S303, the formation process of the conductive structure and the semiconductor body are introduced first.

In some implementations, forming the conductive structure and the semiconductor body comprises: forming a plurality of initial semiconductor bodies extending along the first direction, wherein the plurality of initial semiconductor bodies are separated by an initial dielectric layer; removing part of the initial dielectric layer along the first direction to expose part of the initial semiconductor body, wherein the remaining initial semiconductor body forms the semiconductor body; metallizing at least part of the exposed initial semiconductor body to form a metal semiconductor compound layer; and configuring the metallized exposed initial semiconductor body as the conductive structure.

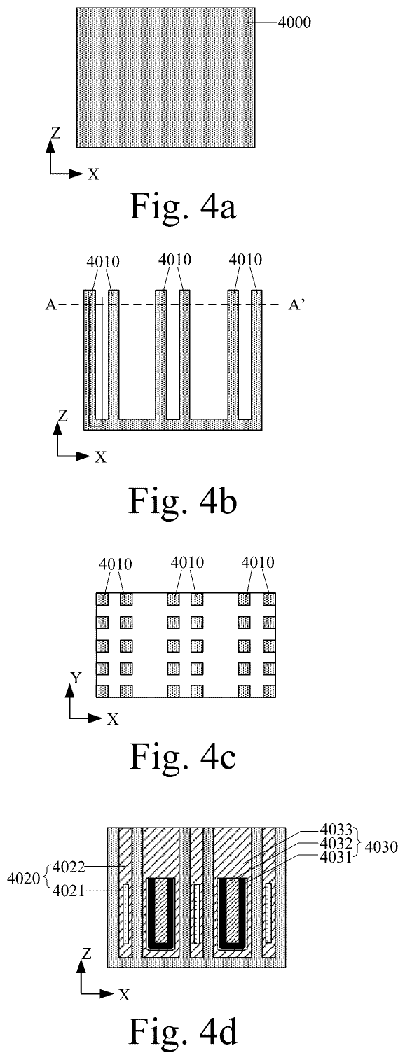

FIGS. 4a to 4d are cross-sectional schematic diagrams during a process of forming an initial semiconductor body provided by implementations of the present disclosure. It is to be noted that FIG. 4c is a cross-sectional schematic view of FIG. 4b along a direction AA′. The formation process of the plurality of initial semiconductor bodies are described in detail below in conjunction with the drawings.

With reference to FIG. 4a, a base 4000 is provided. The base 4000 may comprise a semiconductor material, such as silicon. In an example, the base 4000 may comprise monocrystalline silicon.

With reference to FIGS. 4b and 4c, a plurality of initial semiconductor bodies 4010 arranged in an array are formed in the base 4000. In some implementations, forming the initial semiconductor bodies 4010 may comprise: firstly forming a plurality of trenches extending along the X axis direction in the base 4000; filling the trenches with an insulation material (e.g., silicon oxide); then forming a plurality of trenches extending along the Y axis direction in the base 4000; adjusting the trenches extending along the Y axis direction according to a relative position between a gate structure and the semiconductor body, wherein the trenches extending along the Y axis direction comprise trenches disposed alternately and different in size as shown in FIG. 4B when two gate structures corresponding to two adjacent ones of semiconductor bodies are disposed back to back; and removing the remaining insulation material after filling the trenches to form the initial semiconductor bodies 4010 arranged in the array.

It is to be noted that a shape of a cross section of the initial semiconductor body along the X axis and the Y axis shown in FIG. 4c is a square, and this shape is merely used as an example and not intended to limit the shape of this cross section of the initial semiconductor body and the semiconductor body subsequently formed from the initial semiconductor body, and the shape of this cross section of each of the initial semiconductor body and the semiconductor body may further comprise a rectangle, a circle, an ellipse, a shape approximate to these shapes, etc.

In some other implementations, forming the initial semiconductor bodies 4010 may further comprise: firstly forming a plurality of trenches extending along the Y axis direction in the base 4000; filling the trenches with an insulation material (e.g., silicon oxide); and then forming a plurality of trenches extending along the X axis direction in the base 4000.

In some example implementations, the trenches extending along the X axis direction and/or the Y axis direction may be formed by a lithographic process (which may be construed as lithography-etch (LE) here and below). Filling the trench with the insulation material includes, but is not limited to, a process such as physical vapor deposition (PVD), chemical vapor deposition (CVD) and atomic layer deposition (ALD), etc.

Next, with reference to FIG. 4d, a first isolation structure 4020 and a second isolation structure 4030 are respectively formed in the trenches extending along the Y axis direction according to a requirement of a subsequent manufacture process of the semiconductor device. It will be appreciated that the first isolation structure 4020 here plays a role similar to the trench isolation 1060 in FIG. 1, and the second isolation structure 4030 here plays a role similar to the gate isolation 1062 in FIG. 1.

In some implementations, as shown in FIG. 4d, the first isolation structure 4020 may comprise an air gap 4021 and a cap layer 4022, wherein the air gap 4021 may comprise air; and the cap layer 4022 includes, but is not limited to, silicon oxide. In some other implementations, the first isolation structure 4020 may comprise a conductive material layer and a protection layer (not shown in FIG. 4d). The conductive material layer may play a good role in electrostatic shielding. However, it is to be noted that when the first isolation structure 4020 comprises the conductive material layer, the protection layer needs to surround the conductive material layer to avoid the contact of the conductive material layer with the semiconductor pillar. In some example implementations, forming the first isolation structure 4020 includes, but is not limited to, a process such as PVD, CVD and ALD, etc.

In some implementations, as shown in FIG. 4d, the second isolation structure 4030 may comprise gate structures 4031, a gate spacer layer 4032 between the gate structures, and an initial dielectric layer 4033 over the gate structures, wherein the gate structure 4031 may comprise a gate electrode and a gate dielectric. In an example, the gate structure 4031 may further comprise a blocking layer between the gate electrode and the gate dielectric. The gate electrode may include, but is not limited to, tungsten; the gate dielectric includes, but is not limited to, silicon oxide; and the blocking layer includes, but is not limited to, titanium nitride. The gate spacer layer 4032 and the initial dielectric layer 4033 may comprise the same material or different materials. In an example, the gate spacer layer 4032 and the initial dielectric layer 4033 may each comprise silicon oxide. In some example implementations, forming the gate structure 4031 in the second isolation structure 4030 includes, but is not limited to, a process such as deposition, etching, etc.; forming the gate spacer layer 4022 in the second isolation structure 4030 includes, but is not limited to, a process such as deposition, etching, etc.; and forming the initial dielectric layer 4033 in the second isolation structure 4030 includes, but is not limited to, a process such as deposition, CMP, etc.

It is to be noted that intermediate stages of fabrication are shown from FIG. 2a to following cross-sectional diagrams about the fabrication process. Some structural topographies shown in the figures may be not the final product form of the semiconductor device. For example, the lower ends (ends proximal to the base) of the word lines (gate electrodes) shown in the figures are connected together, while the lower ends of the word lines (gate electrodes) in the final product of the semiconductor device are disconnected, forming a back-to-back arrangement.

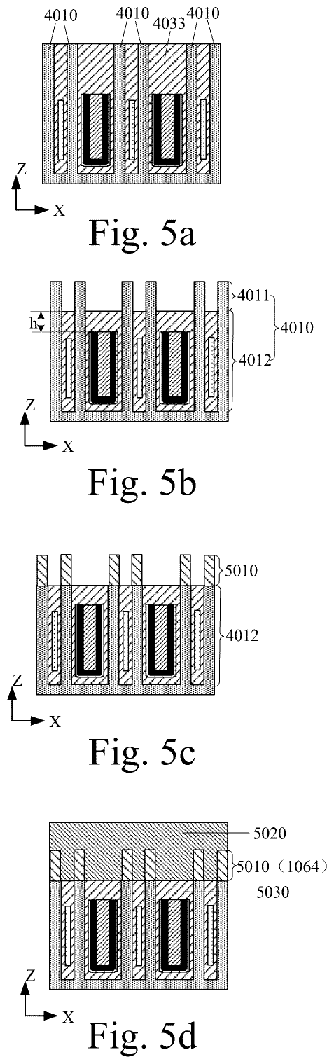

FIGS. 5a to 5d are cross-sectional schematic diagrams I during a process of forming a conductive structure and a semiconductor body provided by implementations of the present disclosure. In the implementations of the present disclosure, an exposed surface of an upper end of the initial semiconductor body is metallized.

In an example, with reference to FIG. 5a, a plurality of initial semiconductor bodies 4010 extending along the Z axis direction are formed, wherein the plurality of initial semiconductor bodies 4010 are separated by an initial dielectric layer 4033. For an example formation implementation of the initial semiconductor body 4010, a reference may be made to the aforementioned implementations shown in FIGS. 4a to 4d.

With reference to FIG. 5b, part of the initial dielectric layer 4033 is removed along the Z axis direction from the top of the initial dielectric layer to expose part of the initial semiconductor body. In this case, the initial semiconductor body 4010 comprises an exposed initial semiconductor body 4011 and an unexposed initial semiconductor body 4012. In some implementations, after part of the initial dielectric layer is removed, a top surface of the remaining initial dielectric layer is higher than a top surface of the gate electrode, that is, there is a height difference h between the remaining initial dielectric layer and the gate electrode. As such, the part of the initial semiconductor body corresponding to the height difference may be used to form a drain or a source of a vertical transistor. In some example implementations, removing part of the initial dielectric layer 4033 includes, but is not limited to, dry etching.

With reference to FIG. 5c, at least part of the exposed initial semiconductor body 4011 is metallized to form a metal semiconductor compound layer 5010. In some example implementations, a metal element in the metal semiconductor compound layer 5010 includes, but is not limited to, nickel, cobalt or titanium, etc.

In some example implementations, forming the metal semiconductor compound layer 5010 may e.g., comprises: forming an initial metal layer (not shown in FIG. 5c) covering an exposed surface (including a top surface and sides of the exposed initial semiconductor body 4011 in FIG. 5b) of a structure to be metallized; and annealing the structure to be metallized formed with the initial metal layer to form the metal semiconductor compound layer.

It is to be noted that the metallization process is mainly performed on the semiconductor material covered with the initial metal layer and not performed on a non-semiconductor material (such as an oxide or nitride material) covered with the initial metal layer. On this basis, after the metal semiconductor compound layer is formed, the superfluous initial metal layer covering the non-semiconductor material usually needs to be removed.

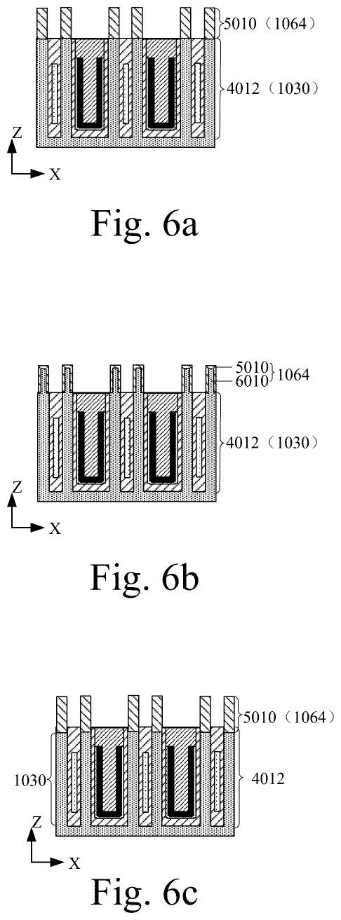

FIGS. 6a to 6c are cross-sectional schematic diagrams I of different proportions of a semiconductor material in a metal semiconductor compound layer during several metallization processes provided by implementations of the present disclosure. It is to be noted that FIGS. 6a to 6c show several possible metallization cases corresponding to FIG. 5c.

In some example implementations, as shown in FIG. 6a, during the metallization process, the exposed initial semiconductor body 4011 is entirely metallized. On this basis, the formed conductive structure 1064 is entirely the metal semiconductor compound layer, and the unexposed initial semiconductor body 4012 forms the semiconductor body 1030.

In some example implementations, as shown in FIG. 6b, during the metallization process, the exposed initial semiconductor body 4011 is partially metallized, and the interior of the exposed initial semiconductor body 4011 is still the semiconductor layer 6010. On this basis, the formed conductive structure 1064 comprises the semiconductor layer 6010 and the metal semiconductor compound layer 5010 surrounding the semiconductor layer 6010, and the unexposed initial semiconductor body 4012 forms the semiconductor body 1030. It will be appreciated that since the semiconductor layer 6010 is actually a portion of the exposed initial semiconductor body 4011, semiconductor layer 6010 comprises the identical material with the entire initial semiconductor body, such as monocrystalline silicon, and has no interface with the unexposed initial semiconductor body 4012.

In some example implementations, as shown in FIG. 6c, during the metallization process, the exposed initial semiconductor body 4011 is entirely metallized, and the metal semiconductor compound layer 5010 further extends into the unexposed initial semiconductor body 4012. It is to be noted that the metal semiconductor compound extending into the unexposed initial semiconductor body 4012 in this case is not necessarily a regular shape shown in FIG. 6c, e.g., having a middle bottom lower than an edge bottom. On this basis, the formed conductive structure 1064 overlaps the unexposed initial semiconductor body 4012 to a certain extent, and in this case, the formed conductive structure 1064 is entirely the metal semiconductor compound layer; meanwhile, a portion of the unexposed initial semiconductor body 4012 that is not metallized forms the semiconductor body 1030.

It will be appreciated that in the aforementioned implementations, a portion of the initial semiconductor body 4010 is directly utilized to form the conductive structure 1064, and meanwhile, the other portion of the initial semiconductor body 4010 forms the semiconductor body 1030. Since the initial semiconductor body 4010 is shaped integrally from bottom to top and the same initial semiconductor body 4010 is shared by the conductive structure 1064 and the semiconductor body 1030, self-alignment of the conductive structure 1064 and the semiconductor body 1030 may be realized directly, and meanwhile, the use of a mask layer is omitted. As such, the accuracy of alignment between the conductive structure and the semiconductor body in the implementations of the present disclosure is higher; the fabrication difficulty of the process is lower; and meanwhile, the mask layer may be not used so that the fabrication flow can be simplified and the fabrication cost of the semiconductor device can be reduced.

Here, the self-alignment may be construed as alignment of geometric centers of the conductive structure 1064 and the semiconductor body 1030, or be construed as alignment of a side of the conductive structure 1064 and a side of the semiconductor body along the Z axis direction, or be construed as overlapping of orthographic projections of cross sections of the conductive structure and the semiconductor body 1030 perpendicular to the first direction. It is to be noted that due to reasons such as a manufacturing error, a tiny deviation occurs between the geometric centers of the conductive structure 1064 and the semiconductor body 1030, or a tiny variation in size of the exposed initial semiconductor body 4011 occurs before and after metallization, etc., which are all within the protection scope of the present disclosure.

In some implementations, with reference to FIG. 5d, after a plurality of conductive structures 1064 are formed, a first dielectric layer 5020 is filled between the plurality of the conductive structures 1064, wherein a top surface of the first dielectric layer 5020 is not lower than a top surface of the conductive structure 1064; the remaining initial dielectric layer forms a second dielectric layer 5030; and a material of the first dielectric layer 5020 is the same as or different from a material of the second dielectric layer 5030. In some example implementations, a material of the first dielectric layer 5020 is the same as a material of the second dielectric layer 5030. For example, both comprise silicon oxide. In some other example implementations, the material of the first dielectric layer 5020 is different from the material of the second dielectric layer 5030. For example, the first dielectric layer 5020 comprises silicon nitride or silicon boronnitride, and the second dielectric layer 5030 comprises silicon oxide. In some example implementations, filling the first dielectric layer 5020 includes, but is not limited to, a process such as PVD, CVD, etc.

It is to be noted that the material of the first dielectric layer 5020 is selected by mainly considering the storage structure formed in the subsequent manufacture process. In an implementation, the storage structure comprises a capacitor, and when the capacitor is formed, due to a longer size of the capacitor along the Z axis direction, a plurality of support layers are usually formed, and an insulation layer filled in the support layers is removed. The insulation layer may include silicon oxide. In order to prevent the removal of the insulation layer between the support layers by wet etching from affecting the first dielectric layer 5020, it is necessary to set the first dielectric layer 5020 as a material having a different etching selectivity ratio from the insulation layer to play a blocking role. Therefore, when the first dielectric layer 5020 comprises silicon nitride or silicon boronnitride, it can directly play a blocking role. When the first dielectric layer 5020 comprises silicon oxide, a layer of material having a different etching selectivity ratio from the insulation layer needs to be formed on the first dielectric layer 5020 before forming the capacitor.

It is to be noted that in a scenario of back-to-back gate structures, the arrangement of a plurality of semiconductor bodies along the X axis is nonuniform, and the conductive structure and the semiconductor body are also arranged nonuniformly along the X axis after being self-aligned, while the storage structures connected with the conductive structures are arranged uniformly along the X axis. In this case, in order to increase a connection window between the conductive structure and the storage structure, the size of the bottom of the storage structure may be expanded. In some example implementations, a size of a cross section of an end of the storage structure proximal to the conductive structure perpendicular to the Z axis direction is greater than a size of a cross section of an end of the storage structure away from the conductive structure perpendicular to the Z axis direction.

In some example implementations, the method further comprises: forming a semiconductor thickening layer at a periphery of the exposed initial semiconductor body by an epitaxy process before metallizing at least part of the exposed initial semiconductor body; at least metallizing at least part of the semiconductor thickening layer and the exposed initial semiconductor body to form the metal semiconductor compound layer; and configuring the metallized exposed initial semiconductor body and semiconductor thickening layer as the conductive structure.

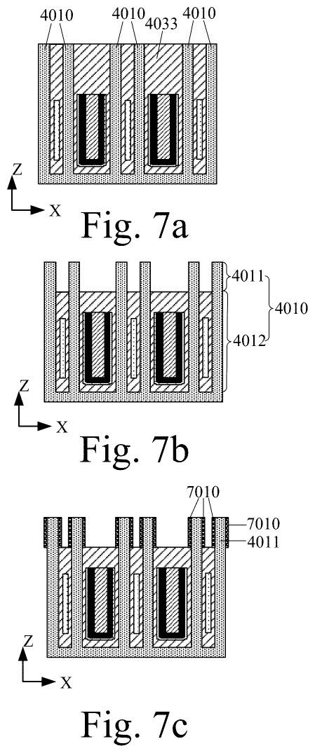

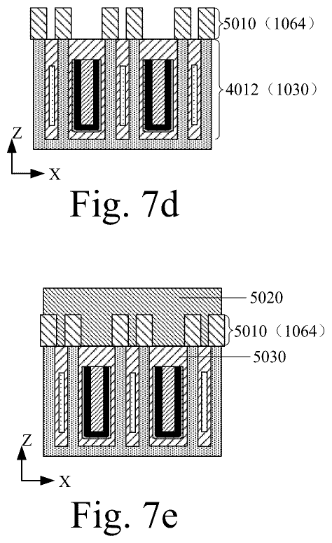

FIGS. 7a to 7e are cross-sectional schematic diagrams II during a process of forming a conductive structure and a semiconductor body provided by implementations of the present disclosure. In the implementations of the present disclosure, an exposed surface of an upper end of the initial semiconductor body is metallized after being thickened.

In an example, with reference to FIG. 7a, a plurality of initial semiconductor bodies 4010 extending along the Z axis direction are formed. The plurality of initial semiconductor bodies 4010 are separated by an initial dielectric layer 4033. For an example formation approach of the initial semiconductor body 4010, a reference may be made to the aforementioned implementations shown in FIGS. 4a to 4d.

With reference to FIG. 7b, part of the initial dielectric layer 4033 is removed along the Z axis direction from the top of the initial dielectric layer to expose part of the initial semiconductor body. In this case, the initial semiconductor body 4010 comprises an exposed initial semiconductor body 4011 and an unexposed initial semiconductor body 4012. An example formation approach of removing part of the initial dielectric layer may be as described above with respect to FIG. 5b.

With reference to FIG. 7c, a semiconductor thickening layer 7010 is formed on all sides of the exposed initial semiconductor body 4011 by an epitaxy process. Here, the semiconductor thickening layer is uniformly formed based on each exposed surface of the exposed initial semiconductor body 4011. That is to say, a size of the semiconductor thickening layer along the Z axis direction varies uniformly, and a size of the semiconductor thickening layer along a direction perpendicular to the Z axis direction also varies uniformly. A shape of a cross section of the combination of the exposed initial semiconductor body 4011 and the semiconductor thickening layer 7010 along a plane formed by an intersection of the X axis and the Y axis is the same as a shape of a cross section of the exposed initial semiconductor body 4011 along the plane. In some example implementations, both the exposed initial semiconductor body 4011 and the semiconductor thickening layer 7010 comprise monocrystalline silicon. In some example implementations, a thickness (½ of a size along the X axis direction) of the semiconductor thickening layer 7010 may be adjusted according to an actual process. In an implementation, the thickness of the semiconductor thickening layer 7010 ranges from 1 nm to 5 nm.

In some implementations, the semiconductor thickening layer 7010 may also be located at a top of the exposed initial semiconductor body 4011 (not shown in FIG. 7c).

With reference to FIG. 7d, at least part of the semiconductor thickening layer 7010 and the exposed initial semiconductor body 4011 are metallized to form a metal semiconductor compound layer 5010. In some example implementations, a metal element in the metal semiconductor compound layer 5010 includes, but is not limited to, nickel, cobalt or titanium, etc.

In some example implementations, forming the metal semiconductor compound layer 5010 comprises: forming an initial metal layer covering an exposed surface (including a top surface of the exposed initial semiconductor body 4011 and sides of the semiconductor thickening layer 7010 in FIG. 7c) of a structure to be metallized; and annealing the structure to be metallized formed with the initial metal layer to form the metal semiconductor compound layer.

It is to be noted that during the metallization process, as a metallization degree differs, the semiconductor material may have different proportions in the metal semiconductor compound layer. In some example implementations, during the metallization process, the exposed initial semiconductor body 4011 and the semiconductor thickening layer 7010 are entirely metallized together. On this basis, the formed conductive structure 1064 is entirely the metal semiconductor compound layer, and the unexposed initial semiconductor body 4012 forms the semiconductor body 1030, as shown in FIG. 7d.

In some example implementations, during the metallization process, the exposed initial semiconductor body 4011 and the semiconductor thickening layer 7010 are partially metallized, and the interior of the exposed initial semiconductor body 4011 is still the semiconductor layer 6010. On this basis, the formed conductive structure 1064 comprises the semiconductor layer 6010 and the metal semiconductor compound layer 5010 surrounding the semiconductor layer 6010, and the unexposed initial semiconductor body 4012 forms the semiconductor body 1030. It will be appreciated that since the semiconductor layer 6010 is actually a portion of the exposed initial semiconductor body 4011, the semiconductor layer 6010 comprise the identical material with the entire initial semiconductor body, such as monocrystalline silicon, and has no interface with the unexposed initial semiconductor body 4012, as will be understood by analogy with reference to FIG. 6b.

In some example implementations, during the metallization process, the exposed initial semiconductor body 4011 and the semiconductor thickening layer 7010 are entirely metallized, and meanwhile, the metal semiconductor compound layer 5010 further extends into the unexposed initial semiconductor body 4012. It is to be noted that the metal semiconductor compound extending into the unexposed initial semiconductor body 4012 in this case is not necessarily a regular shape, e.g., having a middle bottom lower than an edge bottom. On this basis, the formed conductive structure 1064 overlaps the unexposed initial semiconductor body 4012 to a certain extent, and in this case, the formed conductive structure 1064 is entirely the metal semiconductor compound layer, and meanwhile, a portion of the unexposed initial semiconductor body 4012 that is not metallized forms the semiconductor body 1030, as will be understood by analogy with reference to FIG. 6c.

It will be appreciated that in the aforementioned implementations, a portion of the initial semiconductor body 4010 is thickened and metallized to form the conductive structure 1064, and meanwhile, the other portion of the initial semiconductor body 4010 forms the semiconductor body 1030. Since the initial semiconductor body 4010 is shaped integrally from bottom to top and the same initial semiconductor body 4010 is shared by the conductive structure 1064 and the semiconductor body 1030, self-alignment of the conductive structure 1064 and the semiconductor body 1030 may be realized directly. Meanwhile, with the semiconductor thickening layer, the metallized structure is thickened compared to the semiconductor body so that the conductive structure having a greater size can be obtained. Thus, the connection window between the conductive structure and the storage structure is increased, and the effect of further reducing the contact resistance may be also achieved.

In some implementations, with reference to FIG. 7d, after a plurality of conductive structures 1064 are formed, a first dielectric layer 5020 is filled between the plurality of the conductive structures 1064; the remaining initial dielectric layer forms a second dielectric layer 5030; and a material of the first dielectric layer 5020 is the same as or different from a material of the second dielectric layer 5030. In some example implementations, a material of the first dielectric layer 5020 is the same as a material of the second dielectric layer 5030. For example, both comprise silicon oxide. In some other example implementations, the material of the first dielectric layer 5020 is different from the material of the second dielectric layer 5030. For example, the first dielectric layer 5020 comprises silicon nitride or silicon boronnitride, and the second dielectric layer 5030 comprises silicon oxide.

In some implementations, forming the semiconductor body and the conductive structure comprises: forming an initial semiconductor body extending along the first direction, wherein a plurality of initial semiconductor bodies are separated by an initial dielectric layer, and one of two surfaces of the initial semiconductor body disposed oppositely along the first direction is exposed; metallizing part of the initial semiconductor body with the exposed surface to form a metal semiconductor compound layer; and configuring the metal semiconductor compound layer as the conductive structure, wherein the remaining portion of the initial semiconductor body that is not metallized forms the semiconductor body.

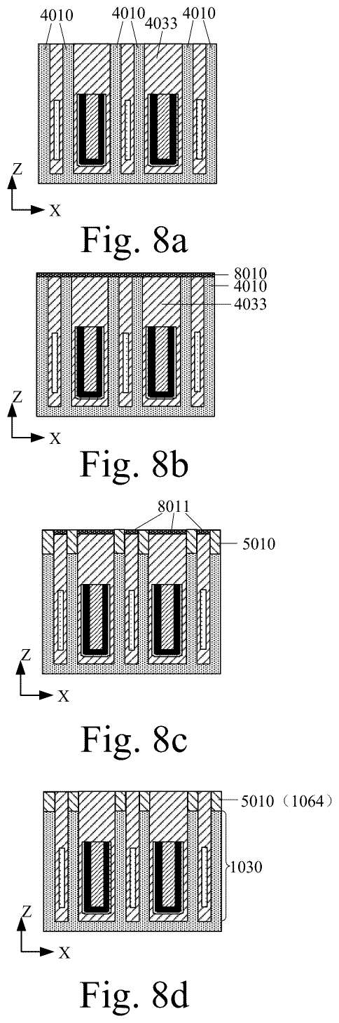

FIGS. 8a to 8d are cross-sectional schematic diagrams III during a process of forming a conductive structure and a semiconductor body provided by implementations of the present disclosure. In the implementations of the present disclosure, an upper end of the initial semiconductor body is metallized by directly utilizing an exposed top surface of the initial semiconductor body.

In an example, with reference to FIG. 8a, a plurality of initial semiconductor bodies 4010 extending along the Z axis direction are formed. The plurality of initial semiconductor bodies 4010 are separated by an initial dielectric layer 4033. For an example formation approach of the initial semiconductor body 4010, a reference may be made to the aforementioned implementations shown in FIGS. 4a to 4d.

With reference to FIG. 8b, an initial metal layer 8010 covering a top surface of the initial semiconductor body 4010. In this case, the initial metal layer 8010 covers the top surface of the initial semiconductor body 4010 and a top surface of the initial dielectric layer 4033, and the structure to be metallized formed with the initial metal layer is annealed. As described previously, the metallization process is mainly performed on the semiconductor material covered with the initial metal layer 8010.

On this basis, with reference to FIG. 8c, part of the initial semiconductor body 4011 with an exposed top surface is metallized to form a metal semiconductor compound layer 5010. In some example implementations, a metal element in the metal semiconductor compound layer 5010 includes, but is not limited to, nickel, cobalt or titanium, etc. The remaining metal layer 8011 covering the top surface of the initial dielectric layer 4033 still exists. The metal semiconductor compound layer is used as the conductive structure 1064, wherein the remaining portion of the initial semiconductor body that is not metallized forms the semiconductor body 1030.

The metallization process is not performed on a non-semiconductor material (such as an oxide or nitride material) covered with the initial metal layer. On this basis, with reference to FIG. 8d, after the metal semiconductor compound layer is formed, the remaining metal layer 8011 covering the non-semiconductor material is removed.

It will be appreciated that in the aforementioned implementations, the exposed top portion of the initial semiconductor body 4010 is directly metallized to form the conductive structure 1064, and meanwhile, the other portion of the initial semiconductor body 4010 forms the semiconductor body 1030. Since the initial semiconductor body 4010 is shaped integrally from bottom to top and the same initial semiconductor body 4010 is shared by the conductive structure 1064 and the semiconductor body 1030, self-alignment of the conductive structure 1064 and the semiconductor body 1030 may be realized directly. Meanwhile, compared with the solution shown in FIGS. 5a-5d, this solution further reduces the process of removing the initial dielectric layer and is simple. The fabrication process is further saved.

It is to be noted that a material of a first dielectric layer between the plurality of the conductive structures is the same as a material of a second dielectric layer between the plurality of the semiconductor bodies. In some example implementations, both materials are silicon oxide. As described previously, in the subsequent process, if an insulation material used when forming the storage structure comprises silicon oxide, then a blocking layer having a different etching selectivity ratio from silicon oxide needs to be formed over the second dielectric layer before forming the storage structure.

It is to be noted that in several aforementioned implementations, since the same semiconductor pillar is shared by the conductive structure and the semiconductor body for forming the vertical transistor, doping ions may be left in the conductive structure no matter whether the source and the drain of the vertical transistor are doped before or after metallization. On this basis, the semiconductor body extends along the first direction; the conductive structure has doping ions therein; and a type of the doping ions is the same as a doping type of doping ions in two opposite ends of the semiconductor body along the first direction.

In some implementations, forming the semiconductor body (semiconductor pillar) and the conductive structure (interconnection structure) comprises: forming a plurality of initial semiconductor bodies extending along the first direction, wherein the plurality of initial semiconductor bodies are separated by an initial dielectric layer; removing part of the initial semiconductor body to form a second trench in the initial dielectric layer, wherein the remaining initial semiconductor body forms the semiconductor body; widening the second trench to form a first trench, wherein a size of the first trench along a second direction perpendicular to the first direction is greater than a size of the second trench along the second direction; and forming the conductive structure in the first trench.

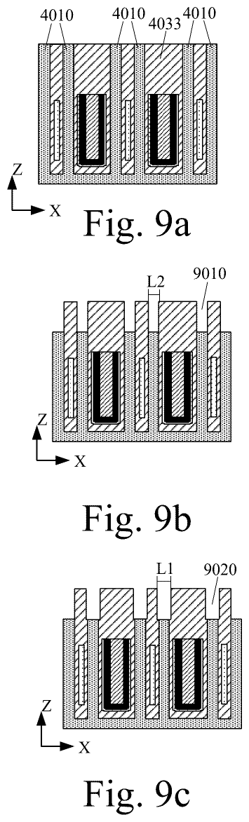

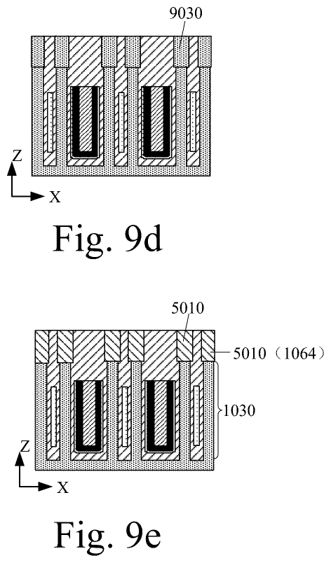

FIGS. 9a to 9e are cross-sectional schematic diagrams IV during a process of forming a conductive structure and a semiconductor body provided by implementations of the present disclosure. In the implementations of the present disclosure, a trench formed after removing an upper end of the initial semiconductor body is widened, and a semiconductor material formed in the widened trench is metallized.

In an example, with reference to FIG. 9a, a plurality of initial semiconductor bodies 4010 extending along the Z axis direction are formed. The plurality of initial semiconductor bodies 4010 are separated by an initial dielectric layer 4033. For an example formation approach of the initial semiconductor body 4010, a reference may be made to the aforementioned implementations shown in FIGS. 4a to 4d.

With reference to FIG. 9b, part of the initial semiconductor body 4010 is removed along the Z axis direction from the top of the initial semiconductor body to form a second trench 9010 in the initial dielectric layer 4033. In some implementations, after part of the initial semiconductor body 4010 is removed, a top surface of the remaining initial semiconductor body is higher than a top surface of the gate electrode, and the remaining initial semiconductor body forms the semiconductor body. In some example implementations, forming the second trench 9010 may include, but is not limited to, dry etching.

It will be appreciated that after part of the initial semiconductor body 4010 is removed, a size of the second trench 9010 along the second direction (i.e., the X axis direction) is the same as a size of the initial semiconductor body 4010 along the second direction (i.e., the X axis direction), and a size of the second trench 9010 along the third direction (i.e., the Y axis direction) is the same as a size of the initial semiconductor body 4010 along the third direction (i.e., the Y axis direction).

In some implementations, with reference to FIG. 9c, part of the initial dielectric layer 4033 on a side of the second trench 9010 is removed, and the second trench 9010 is widened to form a first trench 9020. In some example implementations, removing part of the initial dielectric layer 4033 on the side of the second trench 9010 may include, but is not limited to, dry etching.

It will be appreciated that a size L1 of the first trench 9020 obtained after widening the second trench 9010 along the second direction (i.e., the X axis direction) is greater than a size L2 of the second trench 9010 along the second direction (i.e., the X axis direction); and/or a size of the first trench 9020 along the third direction (i.e., the Y axis direction) is greater than a size of the second trench 9010 along the third direction (i.e., the Y axis direction).

With reference to FIG. 9d, the conductive structure 1064 is formed in the first trench 9020. In some implementations, forming the conductive structure in the first trench 9020 may e.g., comprise: firstly forming an initial semiconductor layer 9030 in the first trench 9020. In some example implementations, the initial semiconductor layer 9030 is formed in the first trench 9020 by a deposition process, and the initial semiconductor layer comprises a polycrystalline material, e.g., polysilicon. In some other example implementations, the initial semiconductor layer 9030 is formed in the first trench 9020 by an epitaxy process, and the initial semiconductor layer comprises a monocrystalline material, e.g., monocrystalline silicon.

With reference to FIG. 9c, the initial semiconductor layer 9030 is metallized to form the metal semiconductor compound layer 5010, and the metal semiconductor compound layer 5010 is used as the conductive structure 1064. An example metallization process may be understood with reference to the aforementioned metallization process.

It is to be noted that in the implementations of the present disclosure, the second trench 9010 may also be not widened, and the metal semiconductor compound layer 5010 is directly formed in the second trench 9010, for obtaining the conductive structure 1064.

In some implementations, forming the semiconductor body and the conductive structure comprises: forming a plurality of initial semiconductor bodies extending along the first direction, wherein the plurality of initial semiconductor bodies are separated by an initial dielectric layer; removing part of the initial dielectric layer along the first direction to expose part of the initial semiconductor body; forming a liner layer covering exposed sides of the initial semiconductor body; filling a first dielectric layer between parts of the liner layer; removing part of the initial semiconductor body, wherein the remaining initial semiconductor body forms the semiconductor body; and the remaining initial dielectric layer forms the second dielectric layer; removing part of the liner layer covering a side of the first dielectric layer to form a plurality of first trenches, wherein the remaining liner layer forms a third dielectric layer; and forming the conductive structure in the first trench.

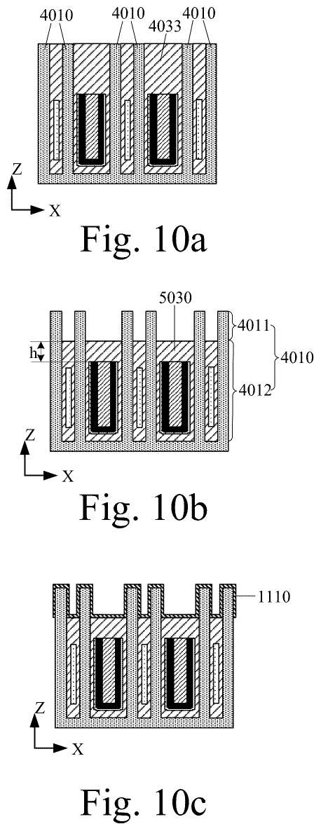

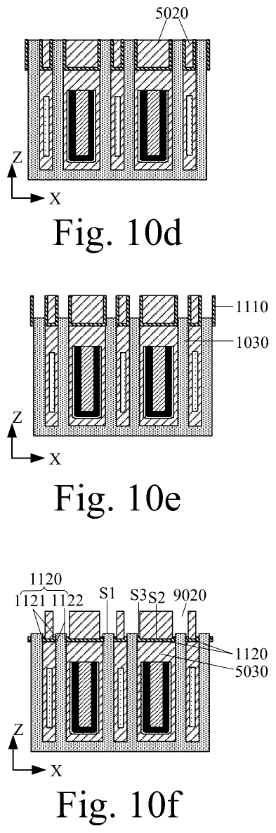

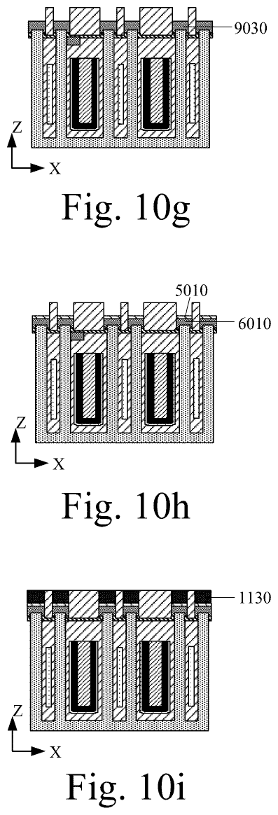

FIGS. 10a to 10i are cross-sectional schematic diagrams V during a process of forming a conductive structure and a semiconductor body provided by implementations of the present disclosure. In the implementations of the present disclosure, by forming a liner layer at a periphery of an exposed upper end of the initial semiconductor body, a semiconductor material having a greater size than the initial semiconductor body is formed subsequently, and is metallized.

In an example, with reference to FIG. 10a, a plurality of initial semiconductor bodies 4010 extending along the Z axis direction are formed, wherein the plurality of initial semiconductor bodies 4010 are separated by an initial dielectric layer 4033. For an example formation approach of the initial semiconductor body 4010, a reference may be made to the aforementioned implementations shown in FIGS. 4a to 4d.

With reference to FIG. 10b, part of the initial dielectric layer 4033 is removed along the Z axis direction from the top of the initial dielectric layer 4033 to expose part of the initial semiconductor body. In this case, the initial semiconductor body 4010 comprises an exposed initial semiconductor body 4011 and an unexposed initial semiconductor body 4012. The remaining initial dielectric layer forms the second dielectric layer 5030. An example formation approach of removing part of the initial dielectric layer may be as described above with respect to FIG. 5b.

With reference to FIG. 10c, a liner layer 1110 is formed on a top surface and a side of the exposed initial semiconductor body 4011. Here, the liner layer 1110 is formed uniformly based on each exposed surface of the exposed initial semiconductor body 4011. That is to say, a size of the liner layer along the Z axis direction varies uniformly, and a size of the liner layer along a direction perpendicular to the Z axis direction varies uniformly as well. A shape of a cross section of the combination of the exposed initial semiconductor body 4011 and the liner layer 1110 along a plane formed by an intersection of the X axis and the Y axis is the same as a shape of a cross section of the exposed initial semiconductor body 4011 along the plane. In some example implementations, forming the liner layer 1110 includes, but is not limited to, a process such as PVD, CVD and ALD, etc. In some example implementations, a thickness (½ of a size along the X axis direction) of the liner layer 1110 may be adjusted according to an actual process. In an implementation, the thickness of the liner layer 1110 ranges from 1 nm to 5 nm.

With reference to FIG. 10d, a first dielectric layer 5020 is filled between parts of the liner layer 1110. In some implementations, etching selectivity ratios of the liner layer 1110 and the first dielectric layer are different. In an implementation, the first dielectric layer 5020 may include an oxide, e.g., silicon oxide; and the liner layer 1110 may include a nitride, e.g., one or more of silicon nitride, silicon oxynitride or a high dielectric material. In some example implementations, forming the first dielectric layer 5020 comprise: depositing a first dielectric material layer between parts of the liner layer 1110 by a process such as PVD, CVD or the like, and removing part of the first dielectric material layer by a process such as CMP or the like, wherein part of the liner layer 1110 on the top of the exposed initial semiconductor body 4011 is removed while part of the first dielectric material layer is removed, so as to expose the top of the exposed initial semiconductor body 4011.

With reference to FIG. 10c, part of the initial semiconductor body is removed along the Z axis direction from the top of the exposed initial semiconductor body 4011, and a surface S1 of the remaining initial semiconductor body is higher than a surface of the liner layer 1110 perpendicular to the first direction. The remaining initial semiconductor body forms the semiconductor body 1030. In some example implementations, removing part of the initial semiconductor body 4011 includes, but is not limited to, a dry etching process.

With reference to FIG. 10f, part of the liner layer 1110 covering the sides of the first dielectric layer 5020 is removed to form a plurality of first trenches 9020; the remaining liner layer 1110 forms the third dielectric layer 1120; and the surface S1 of the remaining initial semiconductor body is higher than a surface S2 of the third dielectric layer proximal to the first dielectric layer. In some example implementations, removing part of the liner layer 1110 covering the sides of the first dielectric layer 5020 includes, but is not limited to, a wet etching process.

In some implementations, the third dielectric layer 1120 may comprise at least a first dielectric sub-layer. The third dielectric layer 1120 may comprise a first dielectric sub-layer 1121 and a second dielectric sub-layer 1122, wherein the first dielectric sub-layer 1121 extends along the second direction (i.e., the X axis direction) and covers the second dielectric layer 5030, and the second dielectric sub-layer 1122 extends along the first direction (i.e., the Z axis direction) and covers part of a side of the initial semiconductor body 4010.

In some implementations, one of two ends of the remaining initial semiconductor body disposed oppositely along the first direction that is proximal to the first trench 9020 extends into the first trench 9020; and the surface S1 of the remaining initial semiconductor body proximal to the first trench 9020 is higher than a surface S3 of the second dielectric sub-layer 1122 proximal to the first trench 9020.

In some implementations, a sum of sizes of the second dielectric sub-layer 1122 and the remaining initial semiconductor body in the second direction (i.e., the Y axis direction) is the same as a size of the first trench 9020 in the second direction (i.e., the Y axis direction).

It will be appreciated that the size of the first trench 9020 along the second direction (i.e., the X axis direction) is greater than the size of the initial semiconductor body 4010 along the second direction (i.e., the X axis direction), and meanwhile, the size of the first trench 9020 along the third direction (i.e., the Y axis direction) is greater than the size of the initial semiconductor body 4010 along the third direction (i.e., the Y axis direction). That is to say, the removel of the liner layer results in the subsequently formed conductive structure having a size greater than the size of the initial semiconductor body, so that the effect of thickening the conductive structure is achieved, and a thickness of the liner layer is a thickness of the conductive structure thickened compared with the initial semiconductor body 4010.

Moreover, the second dielectric layer 5030 may have defects such as voids during filling due to a larger area. Here, S1 is higher than S2 so that the second dielectric layer 5030 can be protected from being exposed. Thus, it can be avoided that an etching fluid enters into the voids to cause an adverse effect when part of the liner layer 1110 on the sides of the first dielectric layer 5020 is removed by wet etching.

Next, with reference to FIGS. 10g, 10 h and 10i, the conductive structure 1064 is formed in the first trench 9020. In some implementations, forming the conductive structure in the first trench comprises: forming an initial semiconductor layer 9030 in the first trench; and metallizing the initial semiconductor layer 9030 to form a metal semiconductor compound layer 5010.

In some example implementations, with reference to FIG. 10g, forming the initial semiconductor layer in the first trench comprises: forming the initial semiconductor layer 9030 in the first trench 9020 by a deposition process, wherein the initial semiconductor layer 9030 comprises a polycrystalline material, e.g., polysilicon.

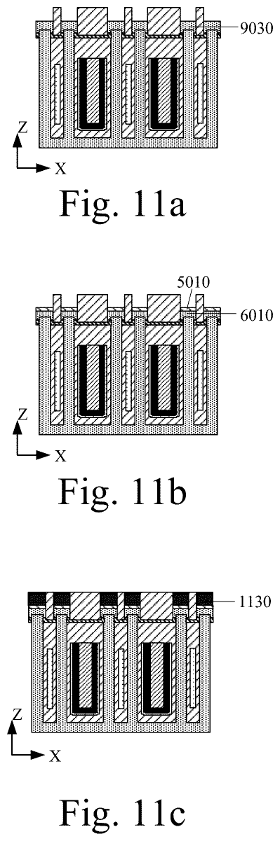

FIGS. 10a to 10f, 11a, 11b and 11c are cross-sectional schematic diagrams VI during a process of forming a conductive structure and a semiconductor body provided by implementations of the present disclosure. That is to say, FIG. 11a is a schematic diagram continued from FIG. 10f.

In some example implementations, with reference to FIG. 11a, forming the initial semiconductor layer in the first trench comprises: forming the initial semiconductor layer 9030 in the first trench 9020 by an epitaxy process, wherein the initial semiconductor layer 9030 comprises a monocrystalline material, e.g., monocrystalline silicon.

Next, with reference to FIGS. 10h and 11b, the initial semiconductor layer 9030 is metallized to form a metal semiconductor compound layer 5010. The initial semiconductor layer 9030 not metallized forms the semiconductor layer 6010.

It is to be noted that here, the metal semiconductor compound layer 5010 extends along the second direction or the third direction. That is to say, a plane where the metal semiconductor compound layer 5010 is located is perpendicular to the first direction. In some example implementations, a metal element in the metal semiconductor compound layer includes, but is not limited to, nickel, cobalt or titanium. An example metallization process may be understood with reference to the aforementioned metallization process. Here, the semiconductor layer 6010 is in contact with the semiconductor body 1030 and is located on a side of the metal semiconductor compound layer 5010 proximal to the semiconductor body 1030.

Next, in some implementations, with reference to FIGS. 10i and 11c, a metal layer 1130 is continuously formed on the metal semiconductor compound layer 5010. The metal layer 1130 is located on a side of the metal semiconductor compound layer away from the semiconductor layer 6010. In some example implementations, the metal layer 1130 includes, but is not limited to, tungsten or copper.

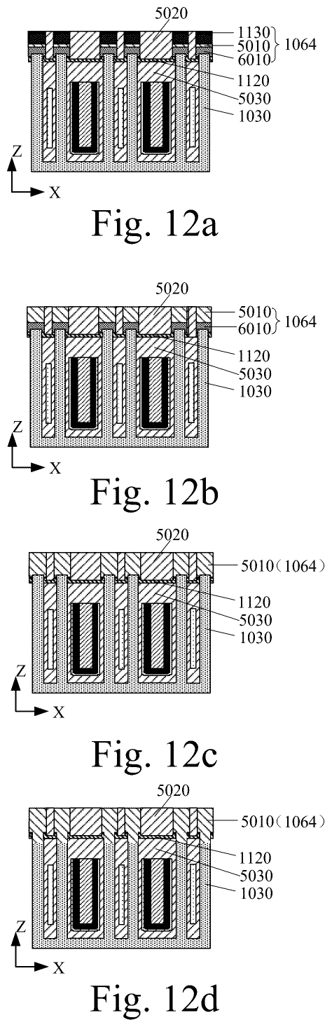

It is to be noted that during the metallization process, as a metallization degree differs, the initial semiconductor may have different proportions in the metal semiconductor compound layer. Moreover, a metal layer may also be added selectively. FIGS. 12a to 12d are cross-sectional schematic diagrams II of different proportions of a semiconductor material in a metal semiconductor compound layer during several metallization processes provided by implementations of the present disclosure.

In some example implementations, as shown in FIG. 12a, during the metallization process, the initial semiconductor layer 9030 is partially metallized. The top of the initial semiconductor layer 9030 is metallized, and the remaining part of the initial semiconductor layer 9030 is not metallized. Meanwhile, a metal layer 1130 is further formed on the top of the initial semiconductor layer 9030. On this basis, the formed conductive structure 1064 comprises the semiconductor layer 6010, the metal semiconductor compound layer 5010 and the metal layer 1130 disposed as being sequentially stacked.

In some example implementations, as shown in FIG. 12b, during the metallization process, the initial semiconductor layer 9030 is partially metallized. The top of the initial semiconductor layer 9030 is metallized, and the remaining part of the initial semiconductor layer 9030 is not metallized. Meanwhile, no metal layer is formed on the top of the initial semiconductor layer 9030. On this basis, the formed conductive structure 1064 comprises the semiconductor layer 6010 and the metal semiconductor compound layer 5010 disposed as being sequentially stacked.

In some example implementations, as shown in FIG. 12c, during the metallization process, the initial semiconductor layer 9030 is entirely metallized, and meanwhile, no metal layer is formed on the top of the initial semiconductor layer 9030. On this basis, the formed conductive structure 1064 is entirely the metal semiconductor compound layer.

In some example implementations, as shown in FIG. 12d, during the metallization process, the initial semiconductor layer 9030 is entirely metallized; meanwhile, the metal semiconductor compound layer 5010 further extends into the initial semiconductor body 4010 below the third dielectric layer; meanwhile, no metal layer is formed on the top of the initial semiconductor layer 9030. On this basis, the formed conductive structure 1064 overlaps the initial semiconductor body 4010 below the third dielectric layer to a certain extent, and in this case, the formed conductive structure 1064 is entirely the metal semiconductor compound layer; meanwhile, a portion of the initial semiconductor body 4010 below the third dielectric layer that is not metallized forms the semiconductor body 1030.

It will be appreciated that in the aforementioned implementations, a portion of the initial semiconductor body 4010 is thickened and metallized to form the conductive structure 1064, and meanwhile, the other portion of the initial semiconductor body 4010 forms the semiconductor body 1030. Since the initial semiconductor body 4010 is shaped integrally from bottom to top and the same initial semiconductor body 4010 is shared by the conductive structure 1064 and the semiconductor body 1030, self-alignment of the conductive structure 1064 and the semiconductor body 1030 may be realized directly. Meanwhile, the initial semiconductor body 4010 is thickened with the liner layer so that the conductive structure having a greater size can be obtained. Thus, the connection window between the conductive structure and the storage structure is increased, and the effect of further reducing the contact resistance may be also achieved.

Meanwhile, by thickening the initial semiconductor body 4010 with the liner layer, the liner layer may be conformally formed on a surface of the initial semiconductor body, and the process controllability is good. Moreover, for the approach of thickening the initial semiconductor body 4010 with the liner layer, there is no need to provide an extra mask layer, which is advantageous to reduce the fabrication cost.

Here, the fabrication of the conductive structure and the semiconductor body is completed. Next, the fabrication of other structures of the semiconductor device is introduced.

In some implementations, operation S303 is performed to form the storage structure connected with the metal semiconductor compound layer on the second surface of the conductive structure. The formation method of the storage structure is mature, which will not be described repeatedly here.

In some implementations, the storage structure comprises a capacitor; and forming the storage structure comprises: forming a cup-shaped capacitor CUP, a cylinder-shaped capacitor CYL or a pillar-shaped capacitor PIL. The shape of the capacitor may be selectively set according to an actual requirement, which will not be limited in the present disclosure.

In some implementations, the fabrication method further comprises: forming a word line on at least one side of the semiconductor body; and forming a bit line on one of two oppositely disposed surfaces of the semiconductor body along the first direction away from the conductive structure.

Here, the word line may extend along the third direction, and the bit line may extend along the second direction.

In some implementations, forming the word line on at least one side of the semiconductor body comprises: forming the word line on one side of the semiconductor body; forming the word line on each of two oppositely disposed sides of the semiconductor body; or forming the word line surrounding a side of the semiconductor body.

It will be appreciated that the conductive structure in the implementations of the present disclosure may be applied to the scenario of different word lines (gate structures). For example, the conductive structure in the implementations of the present disclosure may be applied to the scenario in which two word line structures corresponding to two adjacent semiconductor bodies are disposed back to back. The figures in the implementations of the present disclosure are illustrated using the scenario of the back-to-back arrangement.

In some example implementations, two adjacent semiconductor bodies form one semiconductor body group, and the two semiconductor bodies in one semiconductor body group are separated by a first isolation structure (i.e., the first isolation structure 4020 in FIG. 4d); two adjacent semiconductor body groups are separated by a second isolation structure (i.e., the final form corresponding to the second structure 4030 in FIG. 4d, wherein the lower ends of the gate electrodes are disconnected); and forming the word line on at least one side of the semiconductor body comprises: forming the word line on a side of both sides of a respective semiconductor body in the semiconductor body group away from the first isolation structure.

In the implementations of the present disclosure, by skillfully utilizing the initial semiconductor body, self-alignment of the conductive structure and the semiconductor body can be realized. As such, the alignment accuracy of the conductive structure with the semiconductor body can be improved; the alignment difficulty of both is reduced; the reliability of the semiconductor device is improved; the fabrication time and cost are saved; and the process speed and efficiency are increased. On the other hand, the metal semiconductor compound layer serves as a material of the conductive structure between the semiconductor body and the storage structure, and has a lower electrical resistivity, and can realize a better electrical connection between the semiconductor body and the storage structure and improve the reliability of the semiconductor device.

Implementations of the present disclosure further provide a semiconductor device, comprising: a conductive structure having a first surface and a second surface disposed oppositely along a first direction, wherein the conductive structure comprises at least a metal semiconductor compound layer extending along the first direction; a semiconductor body located on the first surface of the conductive structure and connected with the metal semiconductor compound layer; and a storage structure located on the second surface of the conductive structure and connected with the metal semiconductor compound layer.

In some implementations, the conductive structure is entirely the metal semiconductor compound layer.

In some implementations, the conductive structure further comprises a semiconductor layer that is in contact with the semiconductor body and surrounded by the metal semiconductor compound layer.

In some implementations, a metal element in the metal semiconductor compound layer comprises nickel, cobalt or titanium; and the semiconductor layer comprises a monocrystalline material.

In some implementations, the conductive structure comprises at least a first portion; and a side of the first portion is aligned with a side of the semiconductor body along the first direction.

In some implementations, the conductive structure further comprises a second portion surrounding the first portion; a sum of sizes of cross sections of the first portion and the second portion perpendicular to the first direction is greater than a size of a cross section of the semiconductor device body perpendicular to the first direction.

Here, the first portion may be construed as a portion overlapping a projection of the semiconductor body on a cross section perpendicular to the first direction, and the second portion may be construed as a portion for thickening the semiconductor body in various manners.

In some implementations, the conductive structure and the semiconductor body form a step structure at a joint of the conductive structure and the semiconductor body; and the step structure comprises a side extending along the first direction and a stepped face extending along a second direction perpendicular to the first direction.

In some implementations, a size of the step structure along the second direction is the same in the first direction; and a size of the step structure along the first direction is the same in the second direction.

In some implementations, no interface is present between the semiconductor layer in the conductive structure and the semiconductor body.

In some implementations, the semiconductor body extends along the first direction; the conductive structure has doping ions therein; and a type of the doping ions is the same as a doping type of doping ions in two opposite ends of the semiconductor body along the first direction.

In some implementations, a plurality of the semiconductor bodies and a plurality of the conductive structures are comprised. The semiconductor device further comprises: a first dielectric layer between a plurality of the conductive structures; and a second dielectric layer between a plurality of the semiconductor bodies, wherein the first dielectric layer and the second dielectric layer comprise the same material or different materials; the first dielectric layer and the second dielectric layer both comprise an oxide; or, the first dielectric layer comprises a nitride, and the second dielectric layer comprises an oxide.

In some implementations, a plurality of the semiconductor bodies, a plurality of the conductive structures and a plurality of the storage structures are comprised, and a plurality of the semiconductor bodies are arranged in an array.

The semiconductor device further comprises: a plurality of word lines, wherein each word line is coupled with at least one side of each semiconductor body in one row of the semiconductor bodies; and a plurality of bit lines, wherein each bit line is coupled with one of two oppositely disposed surfaces of each semiconductor body in one column of the semiconductor bodies along the first direction that is away from the conductive structure.

In some implementations, the word line is located on one side of the semiconductor body; or, the word line is located on each of two oppositely disposed sides of the semiconductor body; or, the word line surrounds a side of the semiconductor body.

In some implementations, two adjacent semiconductor bodies form one semiconductor body group, and the two semiconductor bodies in one semiconductor body group are separated by a first isolation structure; two adjacent semiconductor body groups are separated by a second isolation structure; and each of two of the word lines is located on a side of both sides of a respective semiconductor body in the semiconductor body group away from the first isolation structure.

In some implementations, a size of a cross section of an end of the storage structure proximal to the conductive structure perpendicular to the first direction is greater than a size of a cross section of an end of the storage structure away from the conductive structure perpendicular to the first direction.

In some implementations, the storage structure comprises a capacitor; and the capacitor comprises a cup-shaped capacitor, a cylinder-shaped capacitor or a pillar-shaped capacitor.

It is to be noted that the features of the structures in the semiconductor device described above may be understood with reference to the features of the structures described in the fabrication method of the semiconductor device described previously.

In some implementations, the semiconductor device comprises a memory device comprising a DRAM.

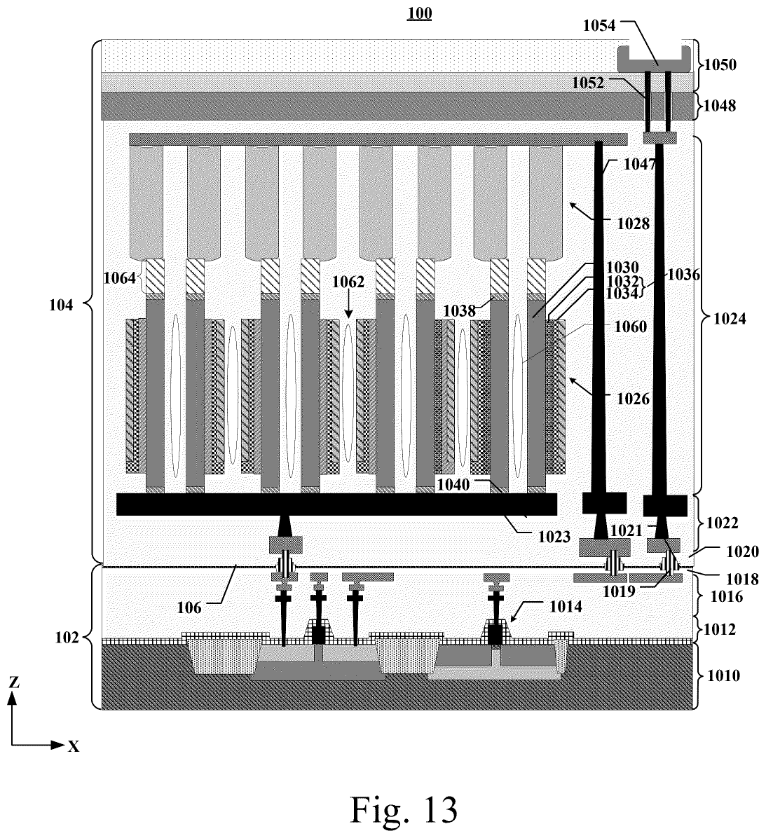

FIG. 13 is a schematic structural diagram II of a dynamic random access memory provided by implementations of the present disclosure. As shown in FIG. 13, a semiconductor device 100 comprises: a conductive structure having a first surface and a second surface disposed oppositely along a first direction, wherein the conductive structure comprises at least a metal semiconductor compound layer extending along the first direction; a semiconductor body located on the first surface of the conductive structure and connected with the metal semiconductor compound layer; and a storage structure located on the second surface of the conductive structure and connected with the metal semiconductor compound layer. Geometric centers of the conductive structure 1064 and the semiconductor body 1030 are disposed as being aligned. It should be appreciated that the alignment here requires ruling out of a tiny deviation caused by a manufacturing error and the like. A size of the conductive structure 1064 along a second direction (e.g., the X axis) is the same as a size of the semiconductor body 1030 along the second direction (e.g., the X axis). It should be appreciated that the “same” here requires ruling out of a tiny size deviation caused by metallization and the like. The conductive structure 1064 comprises a metal semiconductor compound layer extending along the first direction. Other structures shown in FIG. 13 may be understood with reference to FIG. 1.

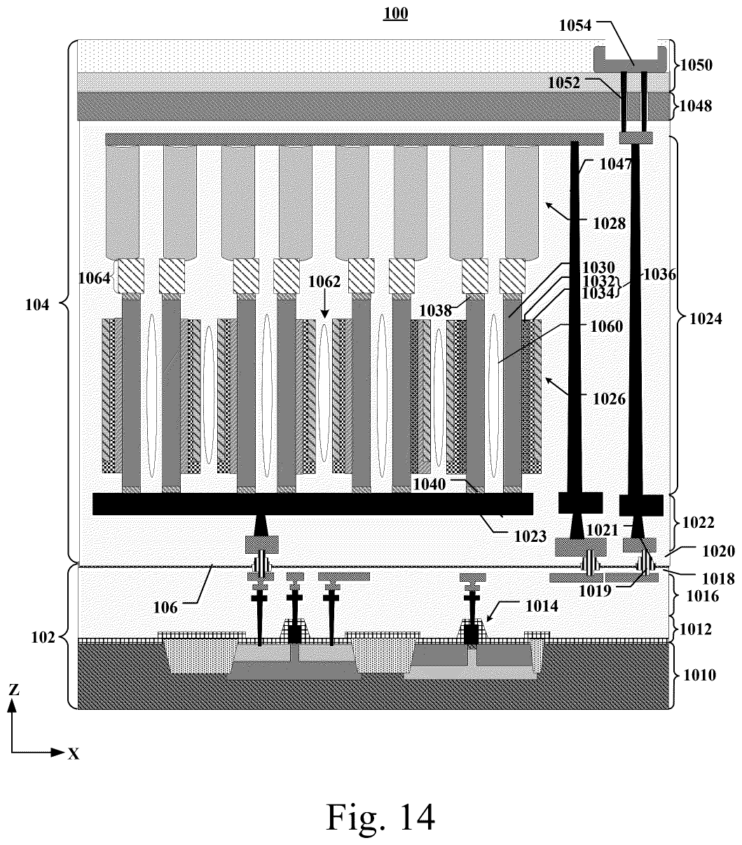

FIG. 14 is a schematic structural diagram III of a dynamic random access memory provided by implementations of the present disclosure. Different from FIG. 13, the size of the conductive structure 1064 along the second direction (e.g., the X axis) is greater than the size of the semiconductor body 1030 along the second direction (e.g., the X axis), and extra sizes of two sides of the conductive structure 1064 relative to the semiconductor body 1030 are the same.

It is to be noted that FIG. 13 and FIG. 14 show only examples of the conductive structure and the semiconductor body in the foregoing implementations of the present disclosure, which may be applied to the dynamic random access memory. It will be appreciated that likewise, other conductive structures and semiconductor bodies in the foregoing implementations of the present disclosure may also be applied to the dynamic random access memory.

It is to be noted that like FIG. 1, FIG. 13 and FIG. 14 show only an example in which the first device 102 and the second device 104 are connected by bonding. It will be appreciated that other conductive structures and semiconductor bodies in the foregoing implementations of the present disclosure may also be applied to the aforementioned case in which the first device 102 and the second device 104 are directly stacked on the same substrate.

It is to be noted that like FIG. 1, FIG. 13 and FIG. 14 show only an example in which two gate structures for two adjacent ones of the semiconductor bodies are disposed back to back. It will be appreciated that other conductive structures and semiconductor bodies in the foregoing implementations of the present disclosure may also be applied to aforementioned various different cases in which the gate structure is located on one side of the semiconductor body, the gate structure is located on each of two opposite sides of the semiconductor body, or the gate structure surrounds the semiconductor body.

Implementations of the present disclosure further provide a memory system, comprising: the semiconductor device in the above implementations of the present disclosure; and a memory controller connected with the semiconductor device and configured to control the semiconductor device.

It is to be noted that the technical solutions as set forth in the implementations of the present disclosure may be combined freely in the case of no conflicts.

The above description is merely example implementations of the present disclosure, and the protection scope of the present disclosure is not limited thereto. Any variation or replacement may easily be made by those skilled in the art without extending beyond the technical scope disclosed by the present disclosure, and shall fall within the protection scope of the present disclosure. Therefore, the protection scope of the present disclosure shall be defined by the protection scope of the claims.

What is claimed is:

1. A semiconductor device, comprising:
a conductive structure having a first surface and a second surface opposite to each other along a first direction, wherein the conductive structure comprises at least a metal semiconductor compound layer extending along the first direction;
a semiconductor body on the first surface of the conductive structure, the semiconductor body being connected with the metal semiconductor compound layer; and
a storage structure on the second surface of the conductive structure, the storage structure being connected with the metal semiconductor compound layer.

2. The semiconductor device according to claim 1, wherein the conductive structure is entirely the metal semiconductor compound layer.

3. The semiconductor device of claim 1, wherein the conductive structure further comprises a semiconductor layer that is in contact with the semiconductor body and surrounded by the metal semiconductor compound layer.

4. The semiconductor device of claim 1, wherein the conductive structure comprises at least a first portion, and a side of the first portion is aligned with a side of the semiconductor body along the first direction.

5. The semiconductor device of claim 4, wherein the conductive structure further comprises a second portion surrounding the first portion, and
wherein a sum of sizes of cross sections of the first portion and the second portion in a first plane perpendicular to the first direction is greater than a size of a cross section of the semiconductor body in a second plane perpendicular to the first direction.

6. The semiconductor device of claim 5, wherein the conductive structure and the semiconductor body form a step structure at a joint of the conductive structure and the semiconductor body, and wherein the step structure comprises a side extending along the first direction and a stepped face extending along a second direction perpendicular to the first direction.

7. The semiconductor device of claim 6, wherein a size of the step structure along the second direction is the same in the first direction; and a size of the step structure along the first direction is the same in the second direction.

8. The semiconductor device of claim 3, wherein no interface is present between the semiconductor layer in the conductive structure and the semiconductor body.

9. The semiconductor device of claim 1, wherein the semiconductor body extends along the first direction, and
wherein a doping type of doping ions in the conductive structure is same as a doping type of doping ions in two opposite ends of the semiconductor body along the first direction.

10. The semiconductor device of claim 1, comprising a plurality of semiconductor bodies including the semiconductor body and a plurality of conductive structures including the conductive structure, and
wherein the semiconductor device further comprises:
a first dielectric layer between the plurality of conductive structures; and
a second dielectric layer between the plurality of semiconductor bodies,
wherein the first dielectric layer and the second dielectric layer comprise a same material or different materials.

11. The semiconductor device of claim 1, comprising a plurality of semiconductor bodies including the semiconductor body and a plurality of conductive structures including the conductive structure, wherein the plurality of the semiconductor bodies are arranged in an array, and
wherein the semiconductor device further comprises:
a plurality of word lines, wherein each word line is coupled with at least one side of
each semiconductor body in one row of the semiconductor bodies; and
a plurality of bit lines, wherein each bit line is coupled with one of two oppositely disposed surfaces of each semiconductor body in one column of the semiconductor bodies along the first direction that is away from the conductive structure.

12. A fabrication method of a semiconductor device, comprising:
forming a conductive structure having a first surface and a second surface opposite to each other along a first direction, wherein the conductive structure comprises at least a metal semiconductor compound layer extending along the first direction;
forming a semiconductor body on the first surface of the conductive structure to be connected with the metal semiconductor compound layer; and
forming a storage structure located on the second surface of the conductive structure to be connected with the metal semiconductor compound layer.

13. The fabrication method of the semiconductor device of claim 12, wherein forming the semiconductor body and the conductive structure comprises:
forming a plurality of initial semiconductor bodies extending along the first direction, wherein the plurality of initial semiconductor bodies are separated by an initial dielectric layer;
removing part of the initial dielectric layer along the first direction to expose a portion of an initial semiconductor body of the plurality of initial semiconductor bodies, wherein a remaining portion of the initial semiconductor body forms the semiconductor body;
metallizing at least part of the exposed portion of the initial semiconductor body to form the metal semiconductor compound layer; and
configuring the metallized at least part of the exposed portion of the initial semiconductor body as the conductive structure.

14. The fabrication method of the semiconductor device of claim 13, further comprising:
forming a semiconductor thickening layer at a periphery of the exposed portion of the initial semiconductor body by an epitaxy process before metallizing the at least part of the exposed portion of the initial semiconductor body;
at least metallizing at least part of the semiconductor thickening layer and the exposed portion of the initial semiconductor body to form the metal semiconductor compound layer; and
configuring the metallized at least part of the exposed portion of the initial semiconductor body and the semiconductor thickening layer as the conductive structure.

15. The fabrication method of the semiconductor device of claim 13, further comprising:
after forming a plurality of conductive structures, filling a first dielectric layer between the plurality of conductive structures, wherein a remaining part of the initial dielectric layer forms a second dielectric layer,
wherein a material of the first dielectric layer is different from a material of the second dielectric layer.

16. The fabrication method of the semiconductor device of claim 12, wherein forming the semiconductor body and the conductive structure comprises:
forming an initial semiconductor body extending along the first direction, wherein a plurality of the initial semiconductor bodies are separated by an initial dielectric layer, and a surface of two surfaces of the initial semiconductor body that are opposite to each other along the first direction is exposed;
metallizing a portion of the initial semiconductor body with the exposed surface of the initial semiconductor body to form the metal semiconductor compound layer; and
configuring the metal semiconductor compound layer as the conductive structure, wherein a remaining portion of the initial semiconductor body that is not metallized forms the semiconductor body.

17. The fabrication method of the semiconductor device of claim 12, wherein forming the semiconductor body and the conductive structure comprises:
forming a plurality of initial semiconductor bodies extending along the first direction, wherein the plurality of initial semiconductor bodies are separated by an initial dielectric layer;
removing a portion of an initial semiconductor body of the plurality of initial semiconductor bodies to form a first trench in the initial dielectric layer, wherein a remaining portion of the initial semiconductor body forms the semiconductor body;
widening the first trench to form a second trench, wherein a size of the second trench along a second direction perpendicular to the first direction is greater than a size of the first trench along the second direction; and
forming the conductive structure in the second trench.

18. The fabrication method of the semiconductor device of claim 17, wherein forming the conductive structure in the second trench comprises:
forming an initial semiconductor layer in the second trench; and
metallizing the initial semiconductor layer to form the metal semiconductor compound layer.

19. The fabrication method of the semiconductor device of claim 18, wherein forming the initial semiconductor layer in the second trench comprises one of:
forming the initial semiconductor layer in the second trench by a deposition process, wherein the initial semiconductor layer comprises a polycrystalline material, or
forming the initial semiconductor layer in the second trench by an epitaxy process, wherein the initial semiconductor layer comprises a monocrystalline material.

20. A system comprising:
a memory device comprising:
a conductive structure having a first surface and a second surface opposite to each other along a first direction, wherein the conductive structure comprises at least a metal semiconductor compound layer extending along the first direction,
a semiconductor body on the first surface of the conductive structure, the semiconductor body being connected with the metal semiconductor compound layer, and
a storage structure on the second surface of the conductive structure, the storage structure being connected with the metal semiconductor compound layer; and
a memory controller coupled to the memory device and configured to control the memory device.
